(19) United States
(12) Patent Application Publication
(10) Pub. No.: US 2026/0331863 A1
(43) Pub. Date: Oct. 22, 2026

(54) LASER AND LASER DEVICE

(71) Applicant: HISENSE LASER DISPLAY CO., LTD., Qingdao (CN)

(72) Inventors: Zinan ZHOU, Qingdao (CN); Youliang TIAN, Qingdao (CN); Wei LI, Qingdao (CN); Xiaofu YU, Qingdao (CN); Xu HAN, Qingdao (CN); Chongyao DUAN, Qingdao (CN); Xin ZHANG, Qingdao (CN); Yao LU, Qingdao (CN); Mengxiao GUO, Qingdao (CN); Zhaoshi GUO, Qingdao (CN); Yunchen LU, Qingdao (CN); Minglong ZHANG, Qingdao (CN)

(73) Assignee: HISENSE LASER DISPLAY CO., LTD., Qingdao (CN)

(21) Appl. No.: 19/700,407

(22) Filed: Jun. 8, 2026

Related U.S. Application Data
(63) Continuation of application No. PCT/CN2024/137594, filed on Dec. 6, 2024.

(30) Foreign Application Priority Data
Dec. 8, 2023 (CN) 202311683844.6
Aug. 14, 2024 (CN) 202411117893.8

(51) Int. Cl. H01S 5/024; H01S 5/023; H01S 5/40

(52) U.S. Cl. CPC H01S 5/02469; H01S 5/023; H01S 5/4087

(57) ABSTRACT

A laser includes a mounting substrate and a light emitting unit. The substrate includes a connection pattern, connection pads, and in-substrate connection wires. The connection pads are electrically connected to the connection pattern via the in-substrate connection wires. The light-emitting unit includes a package and at least two types of light-emitting chips emitting light of different colors. A conductive structure is arranged on a side of the package facing the substrate. The connection pattern includes a conductive pattern, on which the light-emitting unit is fixed and electrically connected. A side wall connection wire is arranged in a side wall of the package, and the light-emitting chips are electrically connected to the side wall connection wire. The connection pads include multiple groups each corresponding to one type of the light-emitting chips, and each group includes two connection pads and is electrically connected to the light-emitting chips of the corresponding type.

### CROSS-REFERENCE TO RELATED APPLICATIONS

This application is a continuation of International Application No. PCT/CN2024/137594, filed on Dec. 6, 2024, which claims priority to China application serial no. 202311683844.6, filed on Dec. 8, 2023 and China application serial no. 202411117893.8, filed on Aug. 14, 2024. The entirety of each of the above-mentioned patent applications is hereby incorporated by reference herein and made a part of this specification.

### BACKGROUND

### Technical Field

The present application relates to the field of photoelectric technologies, and in particular, to a laser and a laser device.

### Description of Related Art

Currently, the laser projection industry is developing rapidly. As one of core components, lasers play an irreplaceable role. A semiconductor laser is formed by packaging a chip after the chip is produced. Therefore, laser packaging capability significantly affects the application, cost, performance, and the like, of the laser. In view of the development of the laser and the demand for color display, a laser package is required to emit a high-quality light beam, so as to reduce the use of optical path components as much as possible when applied to an optical path to miniaturize and simplify a laser display device.

### SUMMARY

Embodiments of the present application provide a laser and a laser device, and the technical solution thereof is as follows.

In an aspect, there is provided a laser, including:
a mounting substrate including a connection pattern, a plurality of connection pads, and a plurality of in-substrate connection wires, at least four of the connection pads being electrically connected to the connection pattern via the plurality of in-substrate connection wires; and
a light-emitting unit, the light-emitting unit including at least one package and a plurality of light-emitting chips arranged in the at least one package, a side of the at least one package facing the mounting substrate including a conductive structure, the connection pattern including a conductive pattern corresponding to the light-emitting unit, the light-emitting unit being fixed on the corresponding conductive pattern and electrically connected to the corresponding conductive pattern, a side wall of the at least one package being provided with at least one side wall connection wire, the at least one light-emitting chip being electrically connected to one side wall connection wire in the side wall of the package where the light-emitting chip is located,
where the light-emitting chips in the light-emitting unit include at least two types of light-emitting chips that emit light of different colors, the plural connection pads include at least two groups of connection pads, each group of connection pads corresponding to one type of the light-emitting chips in the light-emitting unit, each group of connection pads includes two connection pads, and each group of connection pads is electrically connected to the light-emitting chips of the corresponding type.

In another aspect, there is provided a laser device, including the laser in any one of the above descriptions, a light valve assembly and a lens.

### BRIEF DESCRIPTION OF THE DRAWINGS

In order to illustrate the technical solutions in the embodiments of the present application more clearly, the drawings required for describing the embodiments will be described briefly. Apparently, the following described drawings are merely for some embodiments of the present application, and other drawings can be derived from these drawings by those of ordinary skill in the art without any creative effort.

FIG. 1 is a working principle diagram of a laser in the related art;

FIG. 2 is a schematic circuit diagram of a common anode wiring configuration of a laser in the related art;

FIG. 3 is a schematic circuit diagram of a common cathode wiring configuration of a laser in the related art;

FIG. 4 is a schematic external structure diagram of a laser according to some embodiments of the present application;

FIG. 5 is a schematic exploded structure diagram of a laser according to some embodiments of the present application;

FIG. 6 is a schematic side sectional structure diagram of a laser according to some embodiments of the present application;

FIG. 7 is a schematic surface structure diagram of a side of a package facing a mounting substrate in a laser according to some embodiments of the present application;

FIG. 8 is a schematic top structure diagram of a mounting substrate in a laser according to some embodiments of the present application;

FIG. 9 is a schematic side sectional structure diagram of a package in a laser according to some embodiments of the present application;

FIG. 10 is a schematic circuit diagram of a laser according to some embodiments of the present application;

FIG. 11 is a schematic top plane structure diagram of a laser according to some embodiments of the present application;

FIG. 12 is a schematic top structure diagram of another laser according to some embodiments of the present application;

FIG. 13 is a schematic top structure diagram of still another laser according to some embodiments of the present application;

FIG. 14 is a schematic top structure diagram of still another laser according to some embodiments of the present application;

FIG. 15 is a schematic diagram of a circuit connection relationship of a package of still another laser according to some embodiments of the present application;

FIG. 16 is a schematic diagram of an electrical connection relationship in the package of still another laser according to some embodiments of the present application;

FIG. 17 is a schematic internal structure diagram of a package of still another laser according to some embodiments of the present application;

FIG. 18 is a schematic side sectional structure diagram of a package of still another laser according to some embodiments of the present application;

FIG. 19 is a schematic diagram of an electrical connection relationship in a package of still another laser according to some embodiments of the present application;

FIG. 20 is a schematic internal structure diagram of a package of still another laser according to some embodiments of the present application;

FIG. 21 is a schematic side sectional structure diagram of a package of still another laser according to some embodiments of the present application;

FIG. 22 is a schematic structural diagram of a package of still another laser according to some embodiments of the present application;

FIG. 23 is a schematic top structure diagram of still another laser according to some embodiments of the present application;

FIG. 24 is a schematic top plane structure diagram of still another laser according to some embodiments of the present application;

FIG. 25 is a schematic surface structure diagram of a side of a package facing the mounting substrate in still another laser according to some embodiments of the present application;

FIG. 26 is a schematic structural diagram of a package of still another laser according to some embodiments of the present application;

FIG. 27 is a schematic top structure diagram of still another laser according to some embodiments of the present application;

FIG. 28 is a schematic top plane structure diagram of a package of still another laser according to some embodiments of the present application;

FIG. 29 is a schematic top plane structure diagram of still another laser according to some embodiments of the present application;

FIG. 30 is a schematic surface structure diagram of a side of a package facing a mounting substrate in still another laser according to some embodiments of the present application;

FIG. 31 is a schematic top plane structure diagram of still another laser according to some embodiments of the present application;

FIG. 32 is a schematic top plane structure diagram of still another laser according to some embodiments of the present application;

FIG. 33 is a schematic internal structure diagram of a light-emitting unit in a laser according to some embodiments of the present application;

FIG. 34 is a schematic sectional structure diagram of a package in a laser according to some embodiments of the present application;

FIG. 35 is a schematic exploded structure diagram of a package in a laser according to some embodiments of the present application;

FIG. 36 is a schematic internal structure diagram of a package in a laser according to some embodiments of the present application;

FIG. 37 is a schematic internal structure diagram of a package in still another laser according to some embodiments of the present application;

FIG. 38 is a schematic internal structure diagram of a package in still another laser according to some embodiments of the present application;

FIG. 39 is a schematic structural diagram of a laser device according to some embodiments of the present application; and

FIG. 40 is a schematic structural diagram of a laser according to some embodiments of the present application.

### DESCRIPTION OF THE EMBODIMENTS

In order to make the objects and implementations of the present application clearer, the following will clearly and completely describe exemplary implementations of the present application with reference to the accompanying drawings in exemplary embodiments of the present application, and it is obvious that the described exemplary embodiments are only a part of the embodiments of the present application, not all of the embodiments.

It should be noted that the brief descriptions of the terms in the present application are only for the convenience of understanding the implementations described below, and are not intended to limit the implementations of the present application. These terms should be understood according to their ordinary and customary meaning unless otherwise indicated.

The terms “include”, “have” and any variation thereof are intended to cover a non-exclusive inclusion. For example, a product or device that includes a series of assemblies is not necessarily limited to all expressly listed assemblies, but may include other assemblies not expressly listed or inherent in such product or device.

In the present application, unless specified or limited otherwise, the terms such as “mounted”, “connected”, “coupled”, and “fixed”, etc., should be interpreted in a broad sense. For example, it may refer to fixed connections, detachable connections, or integration. It may also be mechanical connections or electrical connections. It may also be direct connections or indirect connections through an intermedium. It may also be internal communication between two components or the interaction relationship between two components, unless otherwise specified. Ordinary skilled persons in the art can understand the specific meanings of the above terms in the present disclosure based on specific circumstances.

In the present disclosure, unless otherwise explicitly specified and limited, if there is a description such as the first feature being “on” or “under” the second feature, it may mean that the first and second features are in direct contact, or the first and second features are in contact indirectly through an intermedium. Additionally, the first feature being “above”, “on top of”, or “on” the second feature may mean that the first feature is directly above or diagonally above the second feature, or it may simply indicate that the horizontal height of the first feature is higher than that of the second feature. The first feature being “below”, “underneath”, or “beneath” the second feature may mean that the first feature is directly below or diagonally below the second feature, or it may simply indicate that the horizontal height of the first feature is lower than that of the second feature.

In the description of the specification, references to “an embodiment”, “some embodiments”, “examples”, “specific examples”, “some examples”, or the like, mean that a particular feature, structure, material, or characteristic described in connection with the embodiment or example is included in at least one embodiment or example of the present application. In this specification, schematic expressions of the above terms do not necessarily refer to the same embodiment or example. In addition, the described particular features, structures, materials, or characteristics may be combined in any suitable manner in any one or more embodiments or examples. Moreover, various embodiments or examples and features of various embodiments or examples described in this specification can be combined and integrated by one skilled in the art without conflicting with one another.

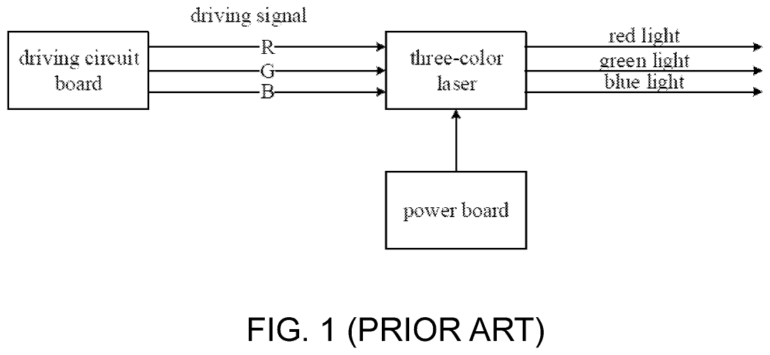

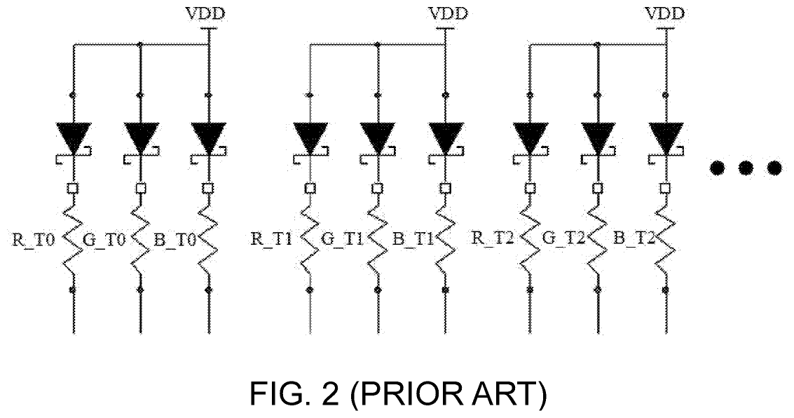

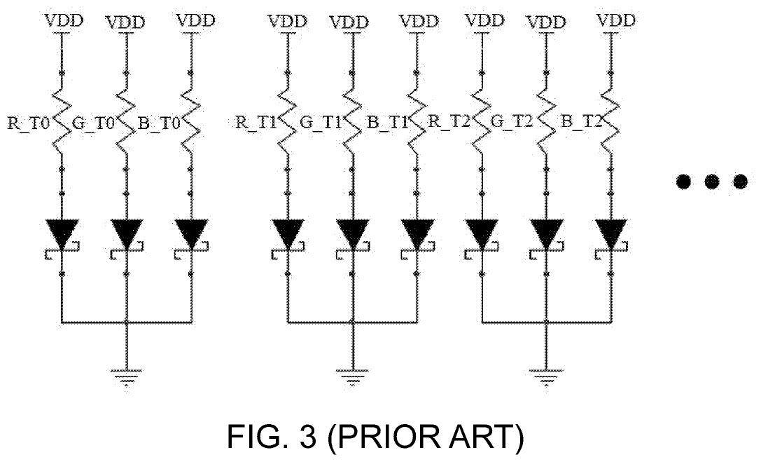

FIG. 1 is a working principle diagram of a laser in the related art, FIG. 2 is a schematic circuit diagram of a common anode wiring configuration of a laser in the related art, and FIG. 3 is a schematic circuit diagram of a common cathode wiring configuration of a laser in the related art. As shown in FIG. 1, in the related art, a driving circuit board is configured to transmit a driving signal to the three-color laser, a power board is configured to supply power to the laser (for example, supply a working voltage VDD), and the laser emits light based on the received driving signal in a power-on state. As shown in FIG. 2 and FIG. 3, three-color light-emitting chips (represented by symbols of diodes) constitute the three-color laser, and resistors R_T, G_T and B_T represent driving circuits of the three-color laser. When a plurality of three-color lasers are required to work simultaneously to increase brightness, the number of the driving circuits increases as the number of the lasers increases (for example, as shown by resistors R_T0, G_T0, B_T0, . . . , R_Tn, G_Tn, and B_Tn in FIG. 2 and FIG. 3), and the increase of the driving circuits leads to an increase in cost.

In order to solve the above technical problem, embodiments of the present application provide a laser and a laser device. The laser includes: a mounting substrate including a connection pattern, a plurality of connection pads, and a plurality of in-substrate connection wires, at least four of the connection pads being electrically connected to the connection pattern through the plurality of in-substrate connection wires. The laser further includes a light-emitting unit, the light-emitting unit including at least one package and a plurality of light-emitting chips arranged inside the at least one package. A conductive structure is arranged on a side of the at least one package facing the mounting substrate. The connection pattern includes a conductive pattern corresponding to the light-emitting unit, the light-emitting unit being fixed on the corresponding conductive pattern and electrically connected to the corresponding conductive pattern. At least one side wall connection wire is arranged in a side wall of the at least one package, and the at least one light-emitting chip is electrically connected to one side wall connection wire in the side wall of the package where the light-emitting chip is located. The light-emitting chips in the light-emitting unit include at least two types of chips that emit light of different colors, the plurality of connection pads include at least two groups of connection pads, each group of connection pads corresponding to one type of the light-emitting chips in the light-emitting unit, each group of connection pads includes two connection pads, and each group of connection pads is electrically connected to the light-emitting chips of the corresponding type. With this arrangement, the light-emitting unit is fixed onto the conductive pattern of the connection pattern of the mounting substrate, and the light-emitting chips of each color are electrically connected to the corresponding two connection pads through the side wall connection wire, the conductive structure, the conductive pattern and the in-substrate connection wire, so that separate power supply for the light-emitting chips of different colors is realized, the problem that the number of the light-emitting chips is limited by the driving circuits is solved, and the number of the driving circuits does not increase while the number of the light-emitting chips increases, thus effectively improving the working efficiency of the driving circuits and reducing the cost.

It should be noted that the light-emitting unit in the embodiments of the present application refers to a smallest repeating unit in the laser including the light-emitting chips of each color. For example, for an RGB laser, the smallest repeating unit including the light-emitting chips of each of the three colors of red, green and blue is one light-emitting unit. In different implementations, the laser may include only one light-emitting unit, or may include a plurality of light-emitting units. In an example, a plurality of light-emitting units are arranged in a row/a column/a plurality of rows and a plurality of columns on the same substrate, and all light-emitting units have the same structure. In different implementations, in each light-emitting unit, the plurality of light-emitting chips of different colors may be all arranged in the same package, or may be respectively arranged in packages of corresponding colors, or may be distributed in a plurality of different packages according to other arbitrary manners.

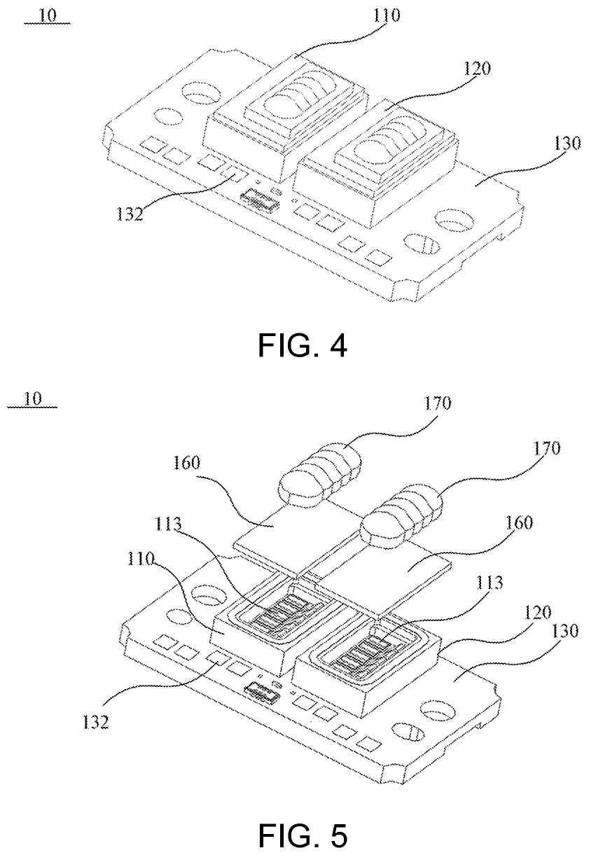

FIG. 4 is a schematic external structure diagram of a laser according to the embodiments of the present application, FIG. 5 is a schematic exploded structure diagram of the laser according to the embodiments of the present application, and the laser shown in FIG. 4 and FIG. 5 includes only one light-emitting unit having dual packages. As shown in FIG. 4, the laser 10 includes a mounting substrate 130 and one light-emitting unit (including a first package 110 and a second package 120). The mounting substrate 130 includes a plurality of connection pads 132 (eight connection pads are shown as an example in FIG. 4). As shown in FIG. 5, a plurality of light-emitting chips 113 are arranged in each of the first package 110 and the second package 120 (five light-emitting chips 113 arranged in a row are shown as an example in FIG. 5). The top of each package 110/120 is provided with a light-transmitting component 160 and a lens assembly 170. The lens assembly 170 is configured to reduce the divergent angle of the divergent light beam emitted by the light-emitting chips 113 to achieve collimation.

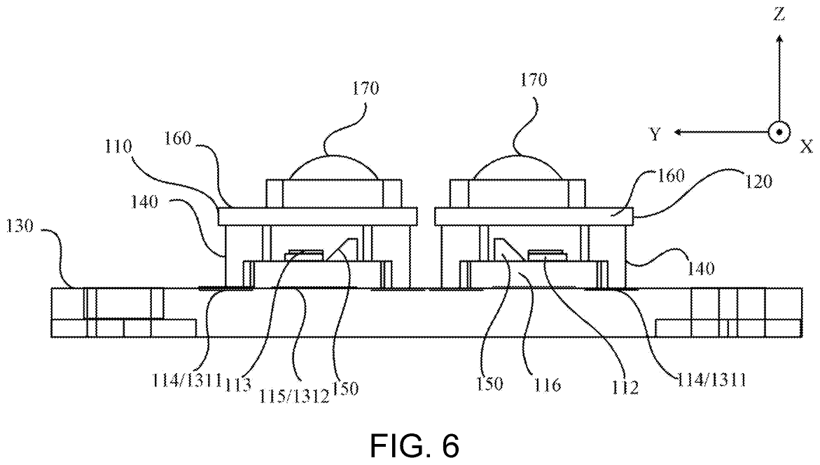

FIG. 6 is a schematic side sectional structure diagram of the laser according to the embodiments of the present application. Referring to FIG. 6, the X-Y plane is a plane parallel to the plane of the mounting substrate, the Z-axis direction is a direction perpendicular to the plane of the mounting substrate, the X-axis direction is a direction along which the light-emitting chips 113 in each package are arranged (i.e., a row direction of the light-emitting chips 113 arranged in a row), and the Y-axis direction is a direction along which the two packages are arranged. As shown in FIG. 6, the mounting substrate 130 includes a connection pattern (including a conductive pattern corresponding to each light-emitting unit, each conductive pattern includes a plurality of transition pads and conductive bases in one-to-one correspondence to the packages, and one conductive pattern including two conductive bases 1312 and a plurality of transition pads 1311 is shown in FIG. 6). The side wall 140 of each of the first package 110 and the second package 120, a package bottom plate 116 at the bottom thereof and the light-transmitting component 160 at the top thereof define a closed space for accommodating the plurality of light-emitting chips 113 and a plurality of reflecting components 150 therein. Referring to FIG. 5 and FIG. 6, one reflecting component 150 is correspondingly arranged on an exit side of each light-emitting chip 113 in each package, and the reflecting component 150 is configured to guide a laser beam from the light-emitting chip 113 to the light-transmitting component 160 and the lens assembly 170 at the top by reflecting the laser beam, so as to realize emission of the laser beam from the laser 10. In some examples, connection wires may be arranged in the package bottom plate 116 and/or the side wall 140. In some examples, the package bottom plate 116 and/or the side wall 140 are made of metal (e.g., a copper-based material) or a ceramic material. In an example, the light emission direction of the plurality of light-emitting chips 113 is parallel to an upper surface of the package bottom plate 116, so that the laser beam emitted by the light-emitting chips 113 is also reflected by the reflecting component 150 to redirect the light emission direction, and therefore, the laser beam travel towards the light-transmitting component 160 and the lens assembly 170 in the direction away from the package bottom plate 116. Reflected laser beam is then passes through the light-transmitting component 160 (e.g., light-transmitting glass) and exits through the lens assembly 170. The light-transmitting component 160 is connected to an end (also referred to as an upper end) of the side wall 140 of the package away from the package bottom plate 116. Exemplarily, the light-transmitting component 160 is made of, for example, sapphire, and is soldered to the upper end of the side wall 140 of the ceramic package by means of AuSn soldering. In an example, the closed space defined by the light-transmitting component 160, the side wall 140 of the package, and the package bottom plate 116 may be filled with nitrogen gas to provide a reliable internal working environment for the light-emitting chips of the laser.

As shown in FIG. 6, each light-emitting unit further includes a plurality of heat sinks 112 in one-to-one correspondence to the plurality of light-emitting chips 113, and each light-emitting chip 113 may be mounted to the package bottom plate 116 through the corresponding heat sink 112. In some embodiments, each light-emitting chip 113 may also be mounted (e.g., by local soldering) on the conductive pattern (the conductive base 1312 corresponding to the package) corresponding to the light-emitting unit via the corresponding heat sink 112.

In addition, as shown in FIG. 6, each package is provided with a conductive structure (including a plurality of bottom pads 114) on a side facing the mounting substrate 130, and the plurality of transition pads 1311 corresponding to each light-emitting unit are connected to the plurality of bottom pads 114 of the conductive structure in a one-to-one correspondence manner.

During operation, the light-emitting chips 113 generate a large amount of heat, and the heat needs to be quickly dissipated to prevent heat accumulation from affecting the light-emitting efficiency of the light-emitting chips. As shown in FIG. 6, the heat sink 112 is arranged below the light-emitting chip 113, and the light-emitting chip 113 is fixedly connected to the heat sink by soldering. For example, the heat sink 112 may be made of a material with a higher thermal conductivity coefficient than oxygen-free copper, such as aluminum nitride, and the heat generated by the light-emitting chip 113 during the light-emitting process can be quickly conducted to the copper heat dissipating package bottom plate 116 below the chip by using the higher thermal conductivity coefficient. The package bottom plate 116 is usually made of an oxygen-free copper material, and the package bottom plate 116 quickly dissipates the heat generated by the light-emitting chip 113 to the surrounding environment with a larger heat dissipation area, so as to lower the junction temperature of the light-emitting chip 113. In some examples, a conductive circuit may also be formed in a region of the package bottom plate 116 and configured to deliver a drive current to the light-emitting chip 113. Since the volume and weight of the heat sink 112 are much larger than those of the light-emitting chip 113, the material of the heat sink 112 may also be aluminum, copper, diamond-copper, or the like. Insulating materials such as aluminum nitride (ALN) and silicon carbide (SIC) are often applied when insulation is required below the light-emitting chip 113.

In an example, the light-emitting chip 113 is soldered to the heat sink 112 by a solder layer. In some examples, the light-emitting chip 113 is soldered through a gold-tin eutectic alloy (AuSn) solder layer using a high precision eutectic soldering machine. For example, main components of the solder layer are Au and Sn, such as Au75Sn25 or Au80Sn20, which may be adjusted according to different specification requirements. Exemplarily, the thickness of the solder layer is approximately 1-10 μm.

In an example, the heat sink 112 includes a multi-layer structure. For example, in the direction away from the light-emitting chip 113, the heat sink 112 includes a titanium (Ti) layer, a platinum (Pt) layer, and a gold (Au) layer in sequence, where the Au layer is next to the AuSn solder layer, and then, the Pt and Ti layers are arranged. The Au layer is mainly configured to assist in soldering of gold wires, and the Pt layer is arranged adjacent to the Au layer and configured to play a bonding role. Besides the function of bonding to the other two layers, the Ti layer also has certain thermal conductivity.

The thicknesses of the Ti layer, the Pt layer and the Au layer depend on actual application, but in most cases, the thickness of each layer is less than 1 μm, in order to conduct the heat as quickly as possible to the side walls 140 of the package.

In some embodiments, the heat sink 112 has a relatively large thermal conductivity coefficient, so that when the light-emitting chip 113 generate heat during emitting light, the heat can be quickly conducted out, and the light-emitting chip 113 is prevented from being damaged by the heat. For example, the heat sink 112 may be made of one or more of aluminum nitride and silicon carbide.

Each light-emitting chip 113 is mounted to the heat sink 112 in a three-dimensional strip shape. A surface of the light-emitting chip 113 contacting the heat sink 112 is a bottom surface, and a projection of the bottom surface on a surface of the heat sink 112 is rectangular. An exit surface of the light-emitting chip 113 is a side perpendicular to the bottom surface, and is also called a side exit surface. The exit surface of the light-emitting chip 113 is rectangular, and the emitted laser beam has different divergence angles along a short side and a long side of the rectangular exit surface. Generally, the directions of different divergence angles of the laser beam correspond to the fast axis direction and the slow axis direction of the laser beam, the direction in which the divergence angle of light exiting the exit surface is large is generally called the fast axis direction, and correspondingly, the direction in which the divergence angle is small is the slow axis direction.

In this example, the plurality of light-emitting chips 113 are all light-emitting chips 113 that emit red light, and since there are two light-emitting points on the exit surface of one red light-emitting chip, the divergence angle of a red laser beam is larger in both the fast axis direction and the slow axis direction than a blue laser beam exiting the exit surface of a blue light-emitting chip and a green laser beam exiting the exit surface of a green light-emitting chip.

As shown in FIG. 6, the plurality of light-emitting chips 113 are soldered to the package bottom plate 116 through the heat sinks 112 respectively. One metal wire of each of the plural light-emitting chips 113 is connected to the light-emitting chip to realize an electrical connection to one electrode of the light-emitting chip, the other metal wire is connected to the corresponding heat sink 112, a region on the heat sink 112 configured to be connected to the metal wire has a conduction relationship or a corresponding relationship with the other electrode of the light-emitting chips 113, and for each light-emitting chip 113, the two metal wires are respectively connected to the light-emitting chip and the heat sink below the light-emitting chip to realize an electrical connection with the outside.

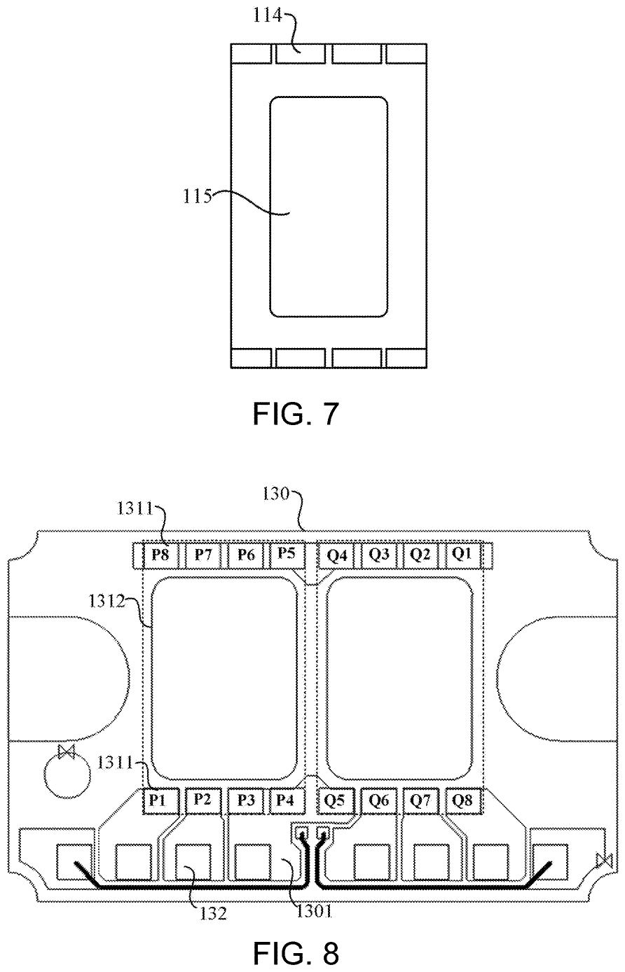

FIG. 7 is a schematic surface structure diagram of a side of the package facing the mounting substrate in the laser according to the embodiment of the present application. FIG. 8 is a schematic top structure diagram of the mounting substrate in the laser according to the embodiment of the present application. Referring to FIG. 7, a side of the package facing the mounting substrate 130 (i.e., a lower surface of the package) is provided with a conductive structure (including a plurality of bottom pads 114, eight bottom pads 114 are shown as an example in FIG. 7) and a connection layer 115. In an example, the connection layer 115 is a substantially rectangular metal film layer. Referring to FIG. 8, the mounting substrate 130 includes a connection pattern (including a conductive pattern corresponding to each light-emitting unit, each conductive pattern includes a plurality of transition pads and conductive bases in one-to-one correspondence to the packages, and one conductive pattern including two conductive bases 1312 and sixteen transition pads 1311 is shown in FIG. 8), a plurality of connection pads 132 (eight connection pads 132 are shown as an example in FIG. 8), and a plurality of in-substrate connection wires 1301, where the connection pads 132 are electrically connected to the transition pads 1311 in the connection pattern through the in-substrate connection wires 1301. The connection pads 132 are configured to be connected to the driving circuit and a power source (for example, the connection pads 132 may be connected to the power source through a connector, a flexible substrate, an epoxy glass substrate, a plate spring terminal, etc.). The conductive base 1312 is a structure configured to be connected to the light-emitting chip 113, has a substantially rectangular shape in a top view, and is matched with the connection layer 115 in shape, size, and position. As an example, as shown in FIG. 8, among the eight connection pads 132 arranged in a row in FIG. 8, the left second connection pad 132 is independently connected to the transition pad 1311 numbered P1 by one in-substrate connection wire 1301, the left third connection pad 132 is independently connected to the transition pad 1311 numbered P2 by one in-substrate connection wire 1301, the left fourth connection pad 132 is independently connected to the transition pad 1311 numbered P3, the transition pad 1311 numbered P4 and the transition pad 1311 numbered Q5 by one in-substrate connection wire 1301, the right second connection pad 132 is independently connected to the transition pad 1311 numbered Q8 by one in-substrate connection wire 1301, the right third connection pad 132 is independently connected to the transition pad 1311 numbered Q7 by one in-substrate connection wire 1301, and the right fourth connection pad 132 is independently connected to the transition pad 1311 numbered Q6 by one in-substrate connection wire 1301. Furthermore, the transition pads 1311 numbered P5, P6, P7, P8, Q1, Q2, Q3, and Q4 are connected together by one in-substrate connection wire 1301.

In an example, referring to FIG. 7, the bottom of each of the first package and the second package is provided with eight bottom pads 114 and one connection layer 115, the total sixteen bottom pads 114 and two connection layers 115 at the bottoms of the two packages are in contact with and electrically connected to one conductive pattern (including sixteen transition pads 1311 and two conductive bases 1312) on the mounting substrate 130—the eight bottom pads in each package are electrically connected to the corresponding eight transition pads 1311 in a one-to-one correspondence manner, and the connection layer 115 in each package is electrically connected to the corresponding conductive base 1312.

In some embodiments of the present application, the light-emitting chips 113 in each light-emitting unit in the laser 10 include at least two types of light-emitting chips that emit light of different colors (that is, the light-emitting chips emitting the same color of light are of the same type). The connection pads 132 on the mounting substrate 130 include at least two groups of connection pads 132, each group of connection pads corresponding to one type the light-emitting chips in the light-emitting unit (i.e., the number of groups of connection pads equals the total number of colors of the light emitted by the light-emitting chips, and each group corresponds to the light-emitting chips emitting light of a same color), each group of connection pads 132 includes two connection pads 132, and each group of connection pads 132 is electrically connected to the light-emitting chips of the corresponding type. In an example, referring to FIG. 6, the light-emitting chips 113 of each color are connected to the corresponding group of connection pads 132 through the side wall connection wires 117 (and/or the connection wires arranged in the package bottom plate 116), the bottom pads 114, the transition pads 1311, and the in-substrate connection wires 1301 in sequence, thereby realizing independent power supply of the light-emitting chips 113 of each color. Each group of connection pads 132 includes two connection pads 132.

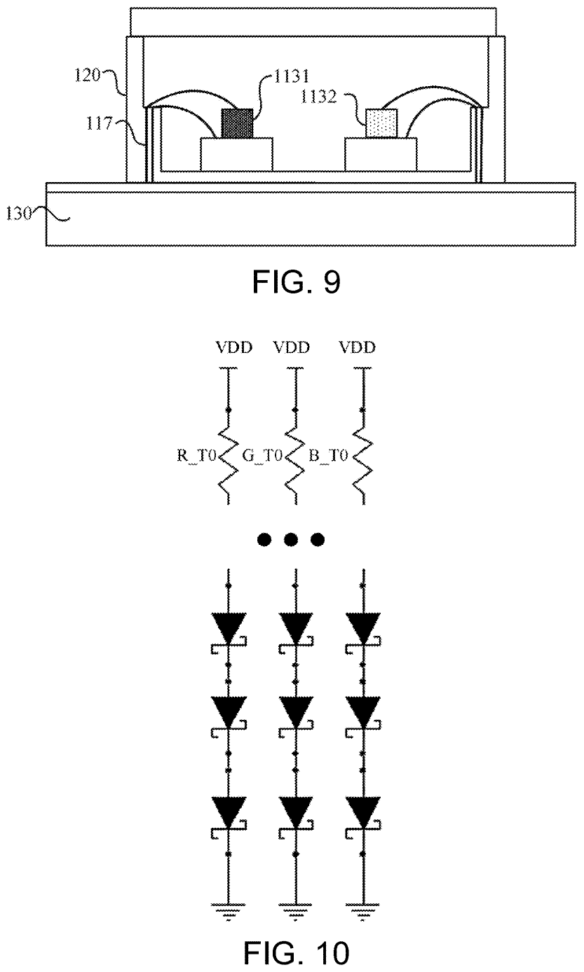

FIG. 9 is a schematic side sectional structure diagram of the package in the laser according to some embodiments of the present application. Referring to FIG. 9, the plurality of light-emitting chips 113 in the second package 120 include first-type light-emitting chips 1131 and second-type light-emitting chips 1132. The first-type light-emitting chips 1131 emit blue laser light, and the second-type light-emitting chips 1132 emit red or green laser light. The first-type light-emitting chips 1131 are electrically connected to the corresponding two connection pads 132, and the second-type light-emitting chips 1132 are electrically connected to the corresponding two connection pads 132, so that at least four connection pads 132 need to be arranged on the mounting substrate 130. It should be noted that FIG. 9 only exemplarily shows the case that the laser includes two types of light-emitting chips with different light-emitting colors, but does not limit the number of the colors of the light-emitting chips included in the laser according to the embodiments of the present application. In another example, the number of the colors of the light-emitting chips included in the laser is three, the three types of light-emitting chips emit laser light of different colors, and the three types of light-emitting chips 113 are electrically connected to the corresponding connection pads 132 through the side wall connection wires 117 of the second package 120 and are separately powered.

FIG. 10 is a schematic circuit diagram of the laser according to some embodiments of the present application. Referring to FIG. 10, the laser includes light-emitting chips 113 of three colors of red, green and blue, and the light-emitting chips 113 of each color are connected in series with a corresponding power source VDD and a driving circuit R_T0, G_T0 or B_10. As can be seen from a comparison with the circuit structure shown in FIG. 2 or FIG. 3, in the embodiments of the present application, no matter how the number of the light-emitting chips 113 is increased, the number of the required driving circuits is not changed, so that the problem that the number of the light-emitting chips is limited by the driving circuits can be solved, the working efficiency of the driving circuits can be effectively improved, and the cost can be reduced.

In some embodiments, in order to achieve independent power supply and meet the requirement of miniaturization design, the mounting substrate 130 is a copper substrate (e.g., a copper printed circuit board), and the copper substrate is a single-sided board (i.e., a single-sided printed board), so that a back surface of the copper substrate has an enough space for heat dissipation, which is beneficial for heat dissipation of the laser. The size of the mounting substrate 130 is not limited in this embodiment, and may be flexibly set as required. In some possible implementations, the mounting substrate 130 is a 15.8 mm×26 mm copper substrate with a thickness of 1.6 mm.

In some possible implementations, the thickness of an electrical connection portion on a surface of a side of the mounting substrate 130 close to the package is 2 oz, about 70 μm. In an example, any one or more of the in-substrate connection wire 1301, the connection pad 132, the transition pad 1311 and the conductive base 1312 have a thickness of 70 μm.

In some possible implementations, as shown in FIG. 8, on a plane perpendicular to the mounting substrate 130, an orthographic projection of the connection pad 132 is at least partially overlapped with an orthographic projection of the in-substrate connection wire 1301, an orthographic projection of the connection pattern (the transition pad 1311 and the conductive base 1312) is at least partially overlapped with the orthographic projection of the in-substrate connection wire 1301, and an orthographic projection of the conductive structure (the bottom pad 114 overlapped with the transition pad 1311) is at least partially overlapped with the orthographic projection of the connection pattern (the transition pad 1311 and the conductive base 1312). The connection pad 132, the in-substrate connection wire 1301, and the connection pattern (the transition pad 1311 and the conductive base 1312) are all located on a surface of a side of the mounting substrate 130 facing the light-emitting unit.

In the direction perpendicular to the plane of the mounting substrate 130, there is an overlapped region between the connection pad 132 and the in-substrate connection wire 1301, i.e., the overlapped region is a connection region of the connection pad 132 and the in-substrate connection wire 1301. The larger the overlapped area between the connection pad 132 and the in-substrate connection wire 1301 is, the more conducive it is to improving the stability of the electrical connection and reducing the contact resistance. The case where the connection pad 132 is at least partially overlapped with the in-substrate connection wire 1301 includes the following cases: the orthographic projection of the connection pad 132 is entirely located within the orthographic projection of the in-substrate connection wire 1301 (as shown in FIG. 8), or parts of the connection pad 132 and the in-substrate connection wire 1301 are overlapped, and the other parts are not overlapped.

In the direction perpendicular to the plane of the mounting substrate 130, there is an overlapped region between the connection pattern (the transition pad 1311 and the conductive base 1312) and the in-substrate connection wire 1301, i.e., the overlapped region is a connection region between the connection pattern (the transition pad 1311 and the conductive base 1312) and the in-substrate connection wire 1301. The larger the overlapped area between the connection pattern (the transition pad 1311 and the conductive base 1312) and the in-substrate connection wire 1301 is, the more conducive it is to improving the stability of the electrical connection and reducing the contact resistance. The case where the connection pattern (the transition pad 1311 and the conductive base 1312) is at least partially overlapped with the in-substrate connection wire 1301 includes the following cases: the orthographic projection of the transition pad 1311 is entirely located within the orthographic projection of the in-substrate connection wire 1301 (as shown in FIG. 8), or parts of the transition pad 1311 and the in-substrate connection wire 1301 are overlapped, and the other parts are not overlapped.

As shown in FIG. 8, in the plane of the mounting substrate 130, the connection pads 132 are located on the same side edge of the mounting substrate 130, that is, on the same side of all the packages, which not only ensures miniaturization of the whole laser, but also makes the appearance of the laser more attractive and facilitates a manual soldering operation. In other possible implementations, the connection pads 132 may also be distributed on two opposite sides of the package.

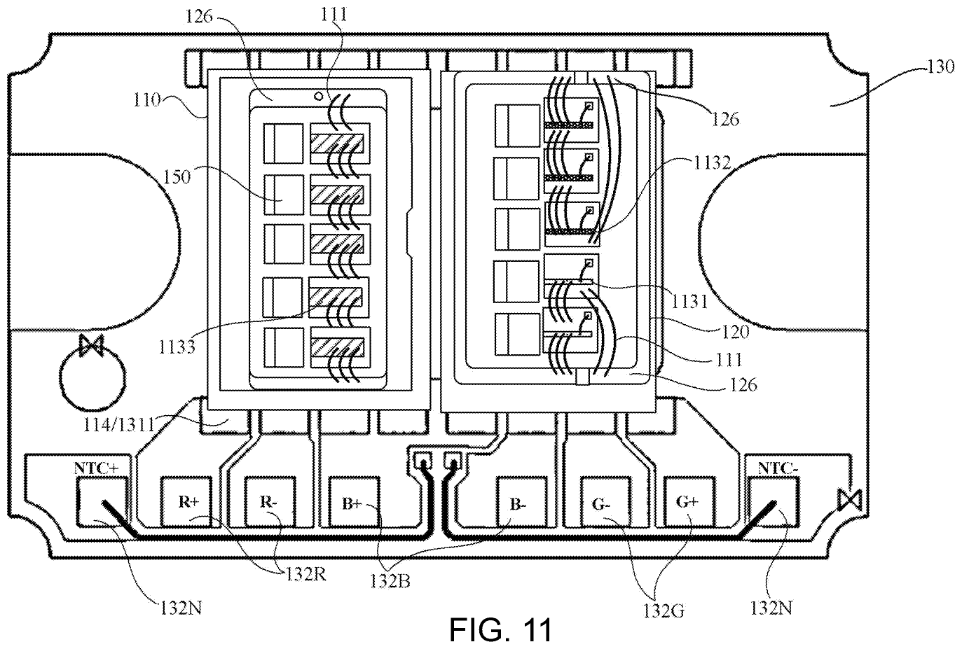

FIG. 11 is a schematic top plane structure diagram of the laser according to some embodiments of the present application. In some embodiments of the present application, the number of the colors of the light-emitting chips included in the laser is three, and each of the light-emitting chips is one of first-type light-emitting chips 1131, second-type light-emitting chips 1132, and third-type light-emitting chips 1133 with different light-emitting colors. As an example, referring to FIG. 9, the light-emitting chips 113 of the same color in the same package are connected in series and respectively connected to two connection pads of the corresponding group of connection pads 132, so as to be respectively connected to the corresponding driving circuit R_T0, G_T0, or B_T0 (and the power source VDD). As an example, referring to FIG. 11, the first-type light-emitting chips 1131 and the second-type light-emitting chips 1132 are packaged inside the second package 120, and the third-type light-emitting chips 1133 are packaged inside the first package 110, herein, the first-type light-emitting chips 1131, the second-type light-emitting chips 1132 and the third-type light-emitting chips 1133 have different center wavelengths and respectively emit laser beams with different colors. Moreover, the center wavelength of the third-type light-emitting chip 1133 is longer than the center wavelengths of the first-type light-emitting chip 1131 and the second-type light-emitting chip 1132, and the center wavelength of the first-type light-emitting chip 1131 is shorter than the center wavelength of the second-type light-emitting chip 1132. As an example, five third-type light-emitting chips 1133 that emit red light are packaged in the first package 110, and two first-type light-emitting chips 1131 that emit blue light and three second-type light-emitting chips 1132 that emit green light are packaged in the second package 110. In the embodiment of the present application, the sum of the numbers of the first-type light-emitting chips 1131 and the second-type light-emitting chips 1132 is the same as the number of the third-type light-emitting chips 1133.

Due to the difference in light-emitting mechanisms, the laser chips that emit different colors of light have different photoelectric conversion efficiencies and different photothermal conversion efficiencies. For example, the thermal conversion power of the red laser chip is high, the light-emitting efficiency is relatively low, and the visual sense function is lower than that of the green laser chip, that is, under the same light-emitting power, human eyes can more easily perceive green. In order to satisfy color matching and brightness requirements for white balance in image display, the numbers of the three types of light-emitting chips may be set such that the number of the red light-emitting chips is greater than both the number of the green light-emitting chips and the number of the blue light-emitting chips, and the number of the green light-emitting chips is greater than the number of the blue light-emitting chips. As an example, the laser shown in FIG. 11 includes two blue light-emitting chips, three green light-emitting chips, and five red light-emitting chips.

In an example, the lens assembly 170 is arranged above the light-transmitting component 160. For example, the lens assembly 170 is connected to the light-transmitting component by way of peripheral dispensing. In this example, the lens assembly 170 is integrally formed with a plurality of collimating lens units, and is configured to reduce the divergence angle of the laser beam with a large divergence angle emitted by the light-emitting chip of the laser, so as to achieve beam collimation. In some implementations, for process identity, lens assemblies with the same curvature and size may be used for the first-type light-emitting chip, the second-type light-emitting chip, and the third-type light-emitting chip. In this example, since the number of the third-type light-emitting chips is equal to the sum of the number of the first-type light-emitting chips and the number of the second-type light-emitting chips, the same type of lens assembly may be used for the two types of light-emitting units, thereby reducing the tooling cost and improving the universality of an optical component. In this example, the curvature of the lens assembly 170 may be set corresponding to the third-type light-emitting chip, i.e., the red light-emitting chip. This is because the red light-emitting chip has two light-emitting points, so that the divergence angles in both the fast axis direction and the slow axis direction are larger than the divergence angles of the other two types of light-emitting chips in the corresponding directions, the influence of the divergence angle of the red laser beam on the divergence angle of combined light is obvious, and collimation of the divergence angle of the red light-emitting chip is preferentially considered when the universal lens assembly is arranged. The lens assemblies are applied to an exit path above the red light-emitting chips and exit paths above the blue and green light-emitting chips.

In some examples, lens assemblies with corresponding curvatures may be respectively arranged for different types or different colors of light-emitting chips, so that the divergence angle of the light beam of each color can be correspondingly reduced to achieve a better collimation effect. In some examples, the third-type light-emitting chips include a plurality of red light-emitting chips with different center wavelengths. Taking the third-type light-emitting chips include five red light-emitting chips as an example for description, in some specific instances, the five red light-emitting chips emit light beams with at least two different center wavelengths, for example, the center wavelengths are 639 nm and 643 nm, or 643 nm and 647 nm, or 639 nm and 647 nm. In some other instances, the five light-emitting chips may emit light beams with three different center wavelengths including 639 nm, 643 nm, and 647 nm respectively, and the numbers of the red light-emitting chips corresponding to the three different center wavelengths may be 1, 2, and 2, or 2, 2 and 1, which is merely illustrated herein, as long as the sum of the numbers of the light-emitting chips corresponding to the different center wavelengths is five, and the specific number of the light-emitting chips corresponding to each center wavelength is not limited. For laser beams of the same color, coherence characteristics between the laser beams can be reduced by setting a plurality of center wavelengths.

In some examples, the light-emitting chips with different center wavelengths are arranged in an ascending order of the center wavelengths. Alternatively, every two light-emitting chips with different center wavelengths are arranged adjacent to each other, and every two light-emitting chips with the same center wavelength are spaced apart from each other.

In an example, two blue light-emitting chips and three green light-emitting chips are sequentially arranged in the second package along the length direction of the second package. In some examples, the center wavelength of the light beam emitted by the blue light-emitting chips is 465 nm, and the center wavelength of the light beam emitted by the green light-emitting chips is 525 nm. In some embodiments, the center wavelengths of the red light-emitting chips arranged in sequence in the first package along the length direction of the first package are in a decreasing trend. The first package and the second package are arranged in parallel, and the lengths, the widths, the sizes in the height direction of the packages are roughly the same. In the direction perpendicular to the length direction of the package, the blue light-emitting chip is arranged adjacent to the red light-emitting chip with a longer center wavelength among the plurality of red light-emitting chips, and the green light-emitting chip is arranged adjacent to the red light-emitting chip with a shorter center wavelength among the plurality of red light-emitting chips. Since the longer the center wavelength of the red light-emitting chip is, the higher the thermal conversion efficiency is, the more easily the heat is generated, and the blue light-emitting chip has a lower thermal efficiency than the green light-emitting chip and the red light-emitting chip, so that under the same drive current, heat generation of the blue light-emitting chip is relatively insignificant. Therefore, in the double-package three-color laser in this example, the blue light-emitting chip in the second package and the red light-emitting chip with a longer center wavelength in the first package are adjacently arranged, the green light-emitting chip in the second package and the red light-emitting chip with a shorter wavelength in the first package are adjacently arranged, and thus, for the whole laser, heat distribution is relatively balanced, which is favorable for dissipating the heat of the laser as a whole to reduce the difficulty of heat dissipating control.

In addition, since the light-emitting efficiency of the red light-emitting chip degrades under the influence of temperature, with the above arrangement, at least heat accumulation in the thermal environment of the red light-emitting chip with a longer center wavelength is not easy to rise rapidly, because except for the red light-emitting chip, the thermal efficiency of the adjacent blue light-emitting chip is relatively low and are less prone to cause rapid thermal changes, which helps stabilize the light-emitting efficiency of the red light-emitting chip, and makes the color of the red laser beam not prone to produce color cast.

In some possible implementations, the number of the connection pads 132 corresponding to each package is two times the number of the colors of the light emitted by the light-emitting chips 113 in the package. The two connection pads 132 in each group of connection pads 132 are a positive polarity pad and a negative polarity pad respectively, and the two connection pads 132 in one group of connection pads 132 connected to the light-emitting chips 113 that emit light of the same color are adjacent to each other. In addition, in some possible implementations, in each light-emitting unit, among all the connection pads 132 connected to the light-emitting chips 113, one of the two adjacent connection pads 132 is a positive polarity pad, and the other is a negative polarity pad.

As shown in FIG. 11, as an example, the number of the connection pads 132 corresponding to the first package 110 is two times the number of the color of the light-emitting chips 113 in the package, i.e., two. The number of the connection pads 132 corresponding to the second package 120 is two times the number of the colors of the light-emitting chips 113 in the package, i.e., four. The group of connection pads 132R corresponding to the third-type light-emitting chips 1133 in the first package 110 includes a red positive polarity pad R+ and a red negative polarity pad R−, the group of connection pads 132B corresponding to the first-type light-emitting chips 1131 in the second package 120 includes a blue positive polarity pad B+ and a blue negative polarity pad B−, the group of connection pads 132B corresponding to the second-type light-emitting chips 1132 in the second package 120 includes a green positive polarity pad G+ and a green negative polarity pad G−, the two connection pads 132 of the same group of these connection pads 132 are adjacent to each other, and the adjacent two connection pads 132 are always a combination of one positive polarity pad and one negative polarity pad.

Referring to FIG. 11, as an example, the five third-type light-emitting chips 1133 in the first package 110 are connected in series via a metal wire 111 (made of, for example, Au) to form a series circuit, two ends of the series circuit are electrically connected to step portions 126 on two sides respectively. A metal film is arranged on an upper surface of the step portion 126, the metal film is electrically connected to the corresponding bottom pad 114 in the conductive structure via the side wall connection wire 117, the bottom pad 114 is electrically connected to the corresponding transition pad 1311 in the conductive pattern of the connection pattern, and the transition pad 1311 is electrically connected to the corresponding connection pad 132R via the in-substrate connection wire 1301, so that the third-type light-emitting chips 1133 are electrically connected to the corresponding group of connection pads 132R. The two first-type light-emitting chips 1131 in the second package 120 are connected in series via a metal wire 111 to form a series circuit, two ends of the series circuit are electrically connected to one metal film on the upper surface of the step portion 126 and are electrically connected to the corresponding bottom pads 114 in the conductive structure via the side wall connection wires 117, the bottom pad 114 is electrically connected to the corresponding transition pad 1311 in the conductive pattern of the connection pattern, and the transition pad 1311 is electrically connected to the corresponding connection pad 132B via the in-substrate connection wire 1301, so that the first-type light-emitting chips 1131 are electrically connected to the corresponding group of connection pads 132B. The three second-type light-emitting chips 1132 in the second package 120 are connected in series via metal wires 111 to form a series circuit, two ends of the series circuit are electrically connected to the other metal film on the upper surface of the step portion 126 and are electrically connected to the corresponding bottom pads 114 in the conductive structure via the side wall connection wires 117, the bottom pad 114 is electrically connected to the corresponding transition pad 1311 in the conductive pattern of the connection pattern, and the transition pad 1311 is electrically connected to the corresponding connection pad 132G via the in-substrate connection wire 1301, so that the second-type light-emitting chips 1132 are electrically connected to the corresponding group of connection pads 132G.

It should be noted that the laser is exemplarily shown to include two packages, but the embodiments of the present application may not be limited thereto. In other possible implementations, the laser 10 includes one package, and the first-type light-emitting chip 1131, the second-type light-emitting chip 1132 and the third-type light-emitting chip 1133 are located in the same package. Alternatively, the laser 10 includes three packages, the first-type light-emitting chip 1131, the second-type light-emitting chip 1132, and the third-type light-emitting chip 1133 are respectively located in the three packages, and the light-emitting chips 113 with the same light-emitting color are located in the same package.

It should also be noted that, the light-emitting chip 113 in the package may be led out by forming a metal film conductive region on an inner wall surface of the side wall 140 of the package, the conductive region is configured to solder a gold wire, and the conductive region is communicated with the side wall connection wire 117. When the conductive region is connected to a positive electrode and a negative electrode or an anode and a cathode of the light-emitting chip, two conductive regions are provided and are not communicated with each other. The two conductive regions are respectively communicated with two wires in the package with opposite electric polarities. Another leading-out way may be as follows: a step portion is formed inwards on the side wall 140 of the package, such as the step portion 126 shown in FIG. 11, a metal film conductive region is arranged on the surface of the step portion 126. By providing the step portion 126, the length of the required metal wire can be shortened or the difficulty of the soldering process for the metal wire and the metal conductive region can be reduced. In some examples, the package is made of a ceramic material, the package bottom plate 116 is made of an oxygen-free copper material, and when the package is disposed on the mounting substrate 130, the pad is only disposed on a region of the mounting substrate 130 corresponding to the package, and a region corresponding to the package bottom plate is an insulation region. In some examples, the side wall connection wire 117 of the first package may also be located inside the side wall 140 of the package and in the package bottom plate 116, and the side wall connection wire 117 may be made of tungsten which has good conductivity.

In the example of FIG. 11, the different types of light-emitting chips each have respective electrode pairs, that is, the different types of light-emitting chips are powered independently, and do not share the anode and the cathode, and therefore, an anode R+ and a cathode R− corresponding to the red light-emitting chip, an anode B+ and a cathode B− corresponding to the blue light-emitting chip, and an anode G+ and a cathode G− corresponding to the green light-emitting chip are respectively arranged at side positions of the mounting substrate 130. Due to independent power supply of the light-emitting chips of different types or different colors, the reliability of power supply can be improved, and for the mounting substrate, the versatility is improved, and the number of the chips arranged inside the package is optional. For example, within a volume that can accommodate five chips at most, three chips or five chips can be arranged. Moreover, the number of the provided light-emitting chips of the same color can be flexibly set, for example, in the first package, the numbers of the provided blue light-emitting chips and green light-emitting chips may be 2 and 3 respectively, or 1 and 4 respectively, or both 2, but all the chips can be electrically connected to corresponding electrode pair pad positions through wiring inside the package.

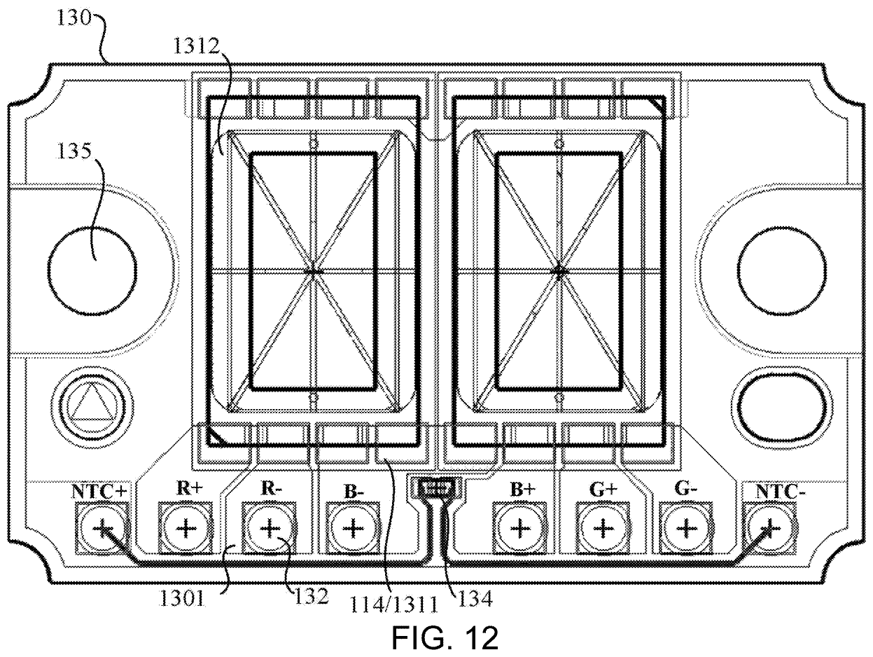

FIG. 12 is a schematic top plane structure diagram of another laser according to some embodiments of the present application. Referring to FIG. 12, as in the laser shown in FIG. 11, the mounting substrate 130 includes four groups of connection pads 132 which are a thermistor positive polarity pad NTC+ and a thermistor negative polarity pad NTC−, a red positive polarity pad R+ and a red negative polarity pad R−, a blue positive polarity pad B+ and a blue negative polarity pad B−, and a green positive polarity pad G+ and a green negative polarity pad G−, respectively. Different from the laser shown in FIG. 11, in order to prevent a short circuit between the positive electrode and the negative electrode caused by a soldering error, the positions of the connection pads 132 are arranged according to the principle that the pads with the same polarity are adjacent, and the arrangement sequence of the eight connection pads 132 from left to right is: the thermistor positive polarity pad NTC+, the red positive polarity pad R+, the red negative polarity pad R−, the blue negative polarity pad B−, the blue positive polarity pad B+, the green positive polarity pad G+, the green negative polarity pad G− and the thermistor negative polarity pad NTC−, that is, the thermistor positive polarity pad NTC+ is adjacent to the red positive polarity pad R+, the red negative polarity pad R− is adjacent to the blue negative polarity pad B−, the blue positive polarity pad B+ is adjacent to the green positive polarity pad G+, and the green negative polarity pad G− is adjacent to the thermistor negative polarity pad NTC−.

In the embodiments of the present application, the connection pads 132 may be configured as, for example, cross pads (as shown in FIG. 12), or any type of pads known to those skilled in the art.

In some possible implementations, as shown in FIG. 12, the laser further includes a thermistor 134, and the thermistor 134 is connected to the corresponding group of connection pads 132 via a connection wire. The thermistor 134 is configured to detect heat generation of the light-emitting chip. The thermistor 134 includes a negative temperature coefficient (NTC) thermistor, or other types of thermistors known to those skilled in the art, and is not limited herein.

Exemplarily, as shown in FIG. 12, the thermistor 134 is located on a side of the conductive base 1312 near the connection pads 132, and the eight connection pads 132 are symmetrically distributed on both sides of the thermistor 134. The group of connection pads 132 (i.e., NTC+ and NTC−) corresponding to the thermistor 134 are located on the outermost sides, and both ends of the thermistor 134 are respectively connected to the thermistor positive polarity pad NTC+ and the thermistor negative polarity pad NTC− via the corresponding connection wires on the mounting substrate 130.

In an example, the third-type light-emitting chip 1133 emits red laser light with a corresponding wavelength range of 613 nm to 760 nm, the first-type light-emitting chip 1131 emits blue laser light with a corresponding wavelength range of 435 nm to 450 nm, and the second-type light-emitting chip 1132 emits green laser light with a corresponding wavelength range of 492 nm to 577 nm. In other possible implementations, one or more of the first-type light-emitting chip 1131, the second-type light-emitting chip 1132 and the third-type light-emitting chip 1133 may also emit laser light of other colors.

Referring to FIG. 12, a positioning hole 135 is generally formed in the mounting substrate 130 for assembly, and when the distance between the package and the positioning hole 135 is reduced to 0.5 mm, wiring cannot be arranged. Therefore, in this embodiment, the bottom pad 114 is only arranged on a side of the package near the connection pad 132, and the bottom pad 114 is electrically connected to the corresponding connection pad 132 via the transition pad 1311 on a side of the mounting substrate 130 near the connection pad 132 and the in-substrate connection wire 1301.

In other possible implementations, under the condition that the distance between the positioning hole 135 and the package and the distance between the packages satisfy a minimum wiring width, the bottom pad 114 may be further arranged on a side of the package away from the connection pad 132, and in this case, the in-substrate connection wire 1301 may be further arranged in the region between the positioning hole 135 on the mounting substrate 130 and the package, and/or the in-substrate connection wire 1301 may be arranged in the region between the two packages on the mounting substrate 130, so that the mutually adjacent transition pads 1311 can be interconnected via the in-substrate connection wires 1301 and then electrically connected to the connection pads 132, thereby increasing the wiring width and reducing the resistance.

Exemplarily, as shown in FIG. 12, the laser includes two packages (i.e., a first package 110 and a second package 120), eight connection pads 132 are located on the same side of the two packages, and four bottom pads 114 are arranged on a side of each package close to the connection pads 132. The mounting substrate corresponding to the first package 110 and the second package 120 is shown in FIG. 8, and referring to FIG. 8 and FIG. 12, in the laser, the transition pad 1311 numbered P1 is connected to the red positive polarity pad R+ via the in-substrate connection wire 1301, and the transition pad 1311 numbered P2 is connected to the red negative polarity pad R− via the in-substrate connection wire 1301, the transition pads 1311 numbered P3, P4, and Q5 are connected to the blue negative polarity pad B− via the in-substrate connection wire 1301, the transition pad 1311 numbered Q6 is connected to the blue positive polarity pad B+, the transition pad 1311 numbered Q7 is connected to the green positive polarity pad G+ via the in-substrate connection wire 1301, and the transition pad 1311 numbered Q8 is connected to the green negative polarity pad G−.

Exemplarily, as shown in FIG. 12, due to the limitation of a wiring space and the addition of the thermistor 134, it is difficult to perform wiring between the transition pad 1311 numbered Q5 and the blue negative polarity pad B−, and the wiring either reduces the area of other wiring or possibly causes the wiring to be overlapped with the thermistor to cause a short circuit. Therefore, by electrically connecting the transition pads 1311 numbered P3 and P4 and the transition pad 1311 numbered Q5 to the blue negative polarity pad B− via the same in-substrate connection wire 1301, on the one hand, the wiring width is increased, thereby reducing the resistance, which is conducive to improving the light-emitting intensity of the light-emitting chip 113, and on the other hand, the placement positions of the thermistor 134 and the connection pad 132 are not affected, and the overall structure is simpler.

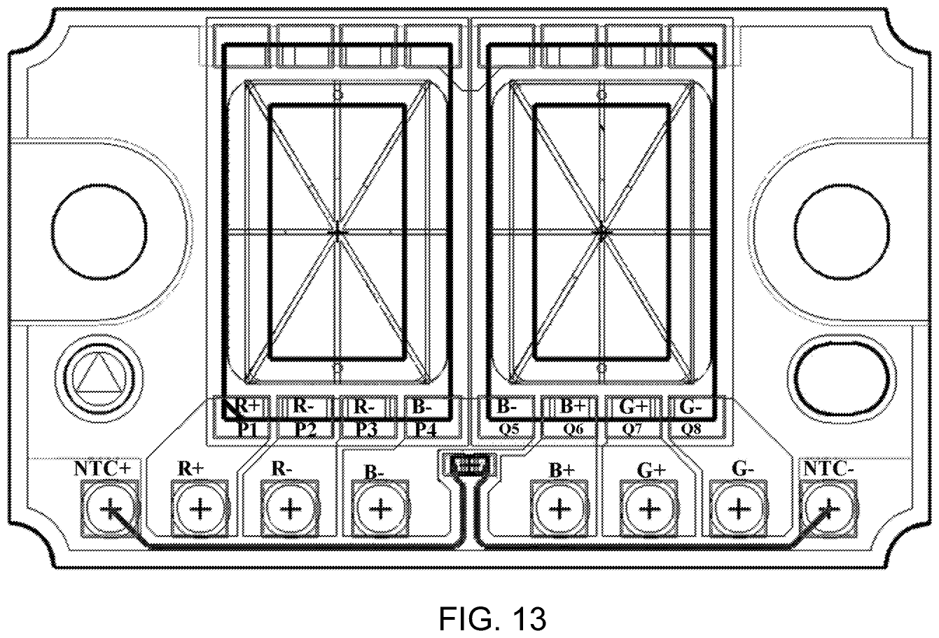

FIG. 13 is a schematic top plane structure diagram of still another laser according to some embodiments of the present application. As another example, referring to FIG. 13, the transition pad 1311 numbered P4 and the transition pad 1311 numbered Q5 are electrically connected to the blue negative polarity pad B− via the same in-substrate connection wire 1301, thus achieving the electrical connection between the blue light-emitting chip and the blue negative polarity pad B−. The transition pad 1311 numbered P3 and the transition pad 1311 numbered P2 are electrically connected to the red negative polarity pad R− via the same in-substrate connection wire 1301, thus achieving the electrical connection between the red light-emitting chip and the red negative polarity pad B−. With this arrangement, the wiring widths of the red negative polarity pad R− and the blue negative polarity pad B− can be doubled, so that the resistance is reduced, the brightness of the light-emitting chip 113 is improved, the placement positions of the thermistor 134 and the connection pad 132 are not influenced, and the overall structure is simpler.

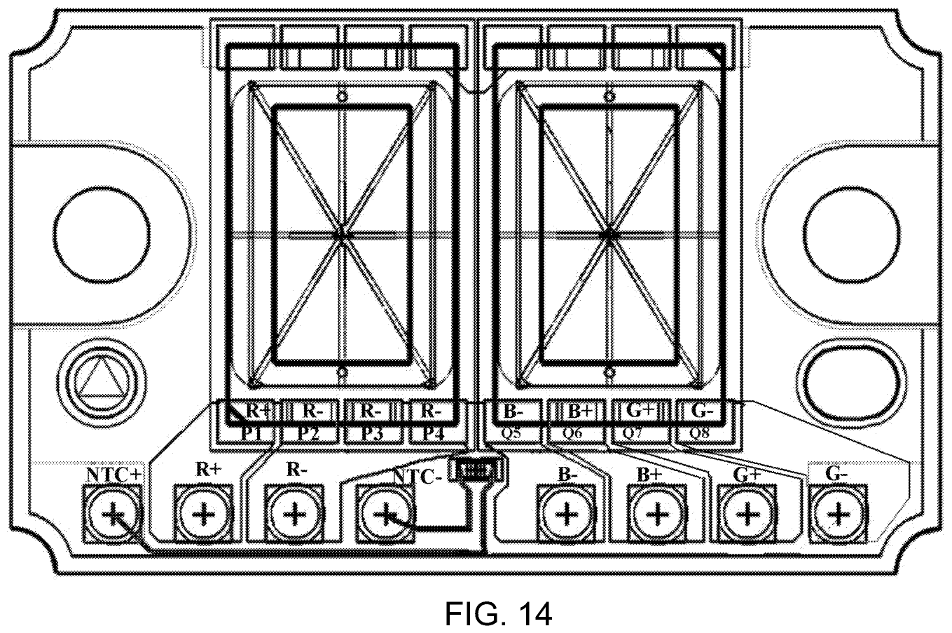

FIG. 14 is a schematic top plane structure diagram of still another laser according to some embodiments of the present application. As another example, referring to FIG. 14, with the position of the thermistor as the boundary, only the red positive polarity pad R+ and the red negative polarity pad R− are arranged on the left side of the thermistor, the blue negative polarity pad B−, the blue positive polarity pad B+, the green positive polarity pad G+, and the green negative polarity pad G− are arranged on the right side of the thermistor, and substantially aligned with the bottom pads of the package, so as to ensure a more uniform wiring width. With this configuration, both the thermistor positive polarity pad NTC+ and the thermistor negative polarity pad NTC− may be arranged on the left side of the thermistor. With this arrangement, each bottom pad 114 of the package can be directly electrically connected to the adjacent connection pad 132, but wiring between the connection pad 132 and the thermistor 134 needs to be readjusted, for example, the space on the lower side of the mounting substrate 130 needs to be increased to accommodate the wiring. Alternatively, the thermistor positive polarity pad NTC+ and the thermistor negative polarity pad NTC− are still respectively arranged on the left and right sides of the thermistor, the numbers of the connection pads 132 on both sides are different, and the area of the connection pad 132 on the right side is reduced, which may reduce the soldering reliability, or the area of the mounting substrate 130 on the right side is increased, which is disadvantageous for miniaturization.

In other possible implementations, if the space requirement of the thermistor is not considered, the transition pads 1311 corresponding to the various light-emitting chips 113 may be arranged in alignment with the bottom pads of the package with equal spacing.

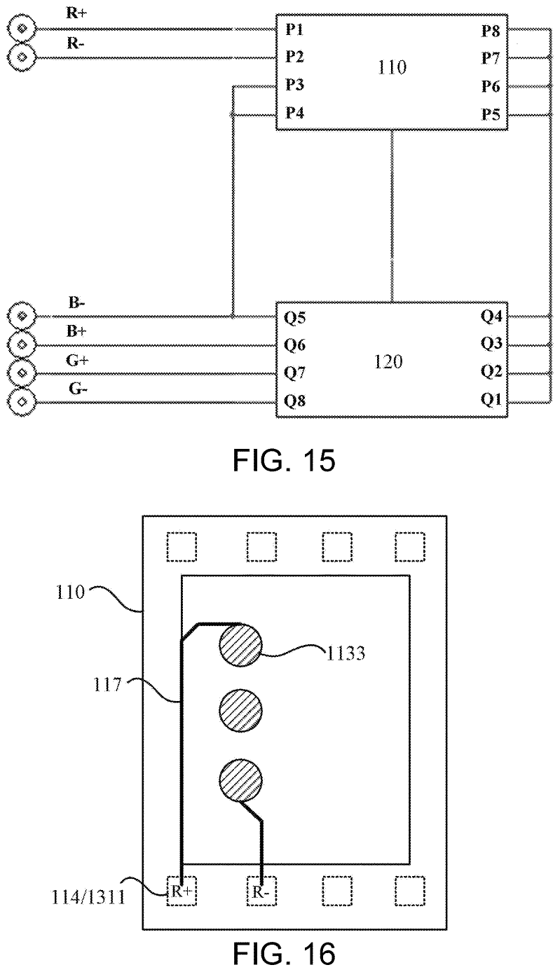

FIG. 15 is a schematic diagram of a circuit connection relationship of the package of still another laser according to some embodiments of the present application. Exemplarily, as shown in FIG. 15, the first package 110 and the second package 120 have the same structure, the second package 120 is obtained by rotating the first package 110 clockwise by 180°, and the connection relationship thereof is the same as the corresponding connection relationship shown in FIG. 8 and FIG. 11, and is not repeated herein.

FIG. 16 is a schematic diagram of an electrical connection relationship in the package of still another laser according to some embodiments of the present application. Referring to FIG. 16, exemplarily, three third-type light-emitting chips 1133 are arranged in the first package 110, and all the third-type light-emitting chips 1133 are connected in series to form a circuit (not shown in FIG. 16). The negative electrode and the positive electrode of the series circuit of the third-type light-emitting chips 1133 are respectively connected to the bottom pads 114 arranged at the bottom of the first package 110 via the side wall connection wires 117 in the first package 110, and the bottom pads 114 are electrically connected to the transition pads 1311 of the mounting substrate 130.

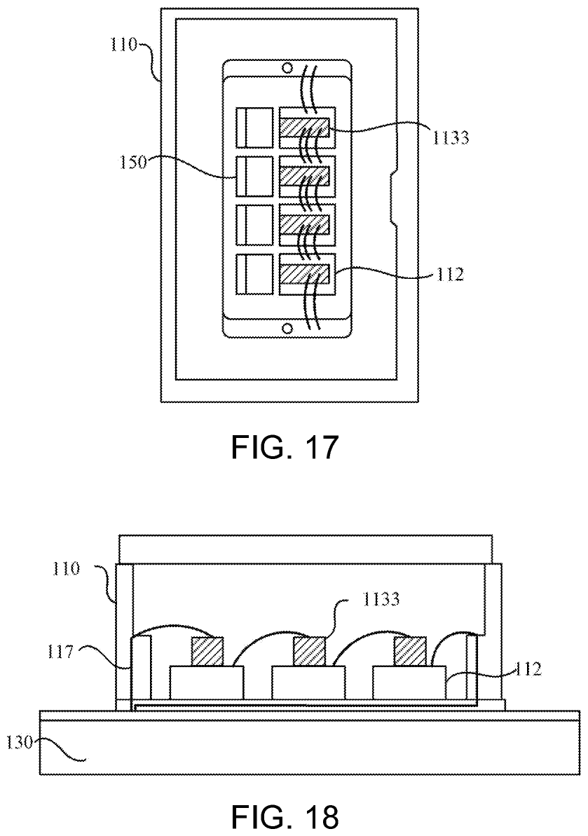

FIG. 17 is a schematic internal structure diagram of the package of still another laser according to some embodiments of the present application. Referring to FIG. 17, exemplarily, four third-type light-emitting chips 1133 are arranged in the first package 110, and all the third-type light-emitting chips 1133 are connected in series via metal wires to form a circuit. The third-type light-emitting chips 1133 are mounted to the corresponding heat sinks 112, and one side of each third-type light-emitting chip is provided with a corresponding reflecting component 150.

FIG. 18 is a schematic side sectional structure diagram of the package of still another laser according to some embodiments of the present application. Referring to FIG. 18, exemplarily, three third-type light-emitting chips 1133 are arranged in the first package 110, each third-type light-emitting chip 1133 is mounted to the corresponding heat sink 112, all the third-type light-emitting chips 1133 are connected in series via metal wires to form a series circuit, and the negative electrode and the positive electrode of the series circuit of the third-type light-emitting chips 1133 are respectively connected to the outside of the package via the side wall connection wires 117 in the first package 110.

In some possible implementations, four or three third-type light-emitting chips 1133 are arranged in the first package 110, all the third-type light-emitting chips 1133 are connected in series to form a series circuit, the negative electrode and the positive electrode of the series circuit of the third-type light-emitting chips 1133 are respectively connected to the bottom pads 114 arranged at the bottom of the first package 110 via the side wall connection wires 117 in the first package 110, the bottom pads 114 are electrically connected to the transition pads 1311 of the mounting substrate 130, and the transition pads 1311 are electrically connected to the connection pads 132 via the in-substrate connection wires 1301, so that the third-type light-emitting chips are electrically connected to the mounting substrate 130. As an example, the side wall connection wires 117 within the first package 110 are located in the side wall 140 and the package bottom plate 116.

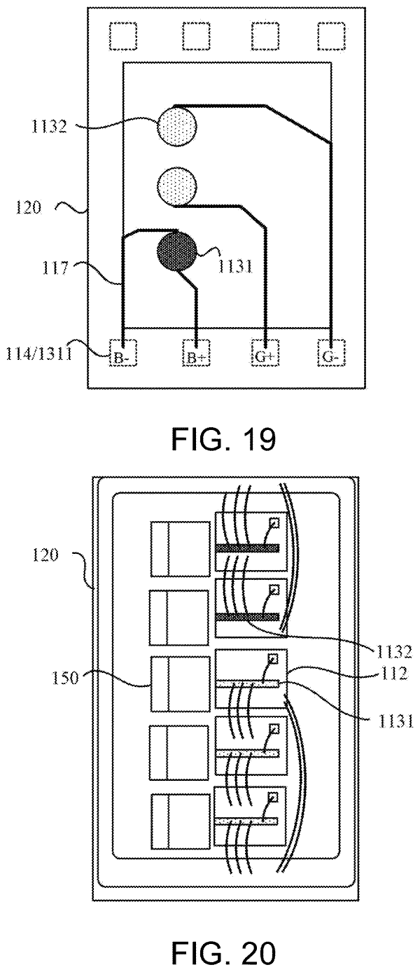

FIG. 19 is a schematic diagram of an electrical connection relationship in the package of still another laser according to some embodiments of the present application. Referring to FIG. 19, exemplarily, one first-type light-emitting chip 1131 and two second-type light-emitting chips 1132 are arranged in the second package 120. All the second-type light-emitting chips 1132 are connected in series to form a series circuit (not shown in FIG. 19). There is no connection between the first-type light-emitting chip 1131 and the second-type light-emitting chips 1132. The positive electrode and the negative electrode of the first-type light-emitting chip 1131 are electrically connected to the bottom pads 114 at the bottom of the second package 120 via the side wall connection wires 117 in the second package 120, and the bottom pads 114 are electrically connected to the transition pads 1311 of the mounting substrate 130. The positive electrode and the negative electrode of the series circuit of the second-type light-emitting chips 1132 are electrically connected to the bottom pads 114 at the bottom of the second package 120 via the side wall connection wires 117 in the second package 120, and the bottom pads 114 are electrically connected to the transition pads 1311 of the mounting substrate 130.

FIG. 20 is a schematic internal structure diagram of the package of still another laser according to some embodiments of the present application. Referring to FIG. 20, exemplarily, three first-type light-emitting chips 1131 and two second-type light-emitting chips 1132 are arranged in the second package 120, all the first-type light-emitting chips 1131 are connected in series via metal wires to form a series circuit, the three first-type light-emitting chips 1131 and the two second-type light-emitting chips 1132 are each mounted to its corresponding heat sinks 112, and the same side thereof is provided with the corresponding reflecting component 150.

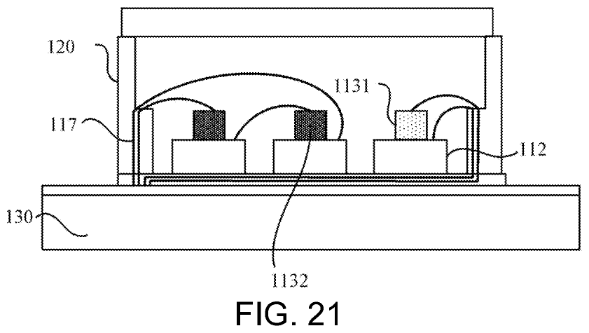

FIG. 21 is a schematic side sectional structure diagram of the package of still another laser according to some embodiments of the present application. Referring to FIG. 21, exemplarily, the second package 120 is provided therein with one first-type light-emitting chip 1131 and two second-type light-emitting chips 1132, which are mounted to the corresponding heat sinks 112. All the second-type light-emitting chips 1132 are connected in series via metal wires to form a series circuit. There is no connection between the first-type light-emitting chip 1131 and the second-type light-emitting chips 1132. The positive electrode and the negative electrode of the first-type light-emitting chip 1131 are respectively connected to the outside of the package via the side wall connection wires 117 in the second package 120. The positive electrode and the negative electrode of the series circuit of the second-type light-emitting chips 1132 are respectively connected to the outside of the package via the side wall connection wires 117 in the second package 120.

In some possible implementations, at least one first-type light-emitting chip 1131 and at least one second-type light-emitting chip 1132 are arranged in the second package 120. All the first-type light-emitting chips 1131 are connected in series to form a series circuit, all the second-type light-emitting chips 1132 are connected in series to form a series circuit, and no connection exists between the first-type light-emitting chips 1131 and the second-type light-emitting chips 1132. The positive electrode and the negative electrode of the series circuit of the first-type light-emitting chips 1131 are electrically connected to the bottom pads 114 at the bottom of the second package 120 via the side wall connection wires 117 in the second package 120, the bottom pads 114 are electrically connected to the transition pads 1311 of the mounting substrate 130, and the transition pads 1311 are electrically connected to the corresponding transition pads 132 via the in-substrate connection wires 1301. The positive electrode and the negative electrode of the series circuit of the second-type light-emitting chips 1132 are electrically connected to the bottom pads 114 at the bottom of the second package 120 via the side wall connection wires 117 in the second package 120, the bottom pads 114 are electrically connected to the transition pads 1311 of the mounting substrate 130, and the transition pads 1311 are connected to the corresponding transition pads 1311 via the in-substrate connection wires 1301. In this way, the electrical connection between the first-type light-emitting chip 1131 and the mounting substrate 130, and the electrical connection between the second-type light-emitting chip and the mounting substrate 130 are realized. As an example, the side wall connection wires 117 within the second package 120 are located in the side wall 140 and the package bottom plate 116.

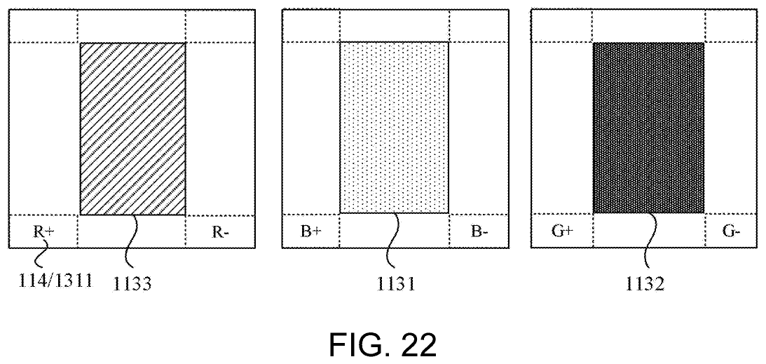

FIG. 22 is a schematic structural diagram of the package of still another laser according to some embodiments of the present application. Referring to FIG. 22, exemplarily, the three types of light-emitting chips of different colors in the same light-emitting unit are respectively arranged in three different packages. On the side of the package facing the mounting substrate 130, two bottom pads 114 arranged side by side are provided on the side of each package adjacent to the connection pads 132. The two bottom pads 114 under each package are connected to the corresponding transition pads 1311 respectively.

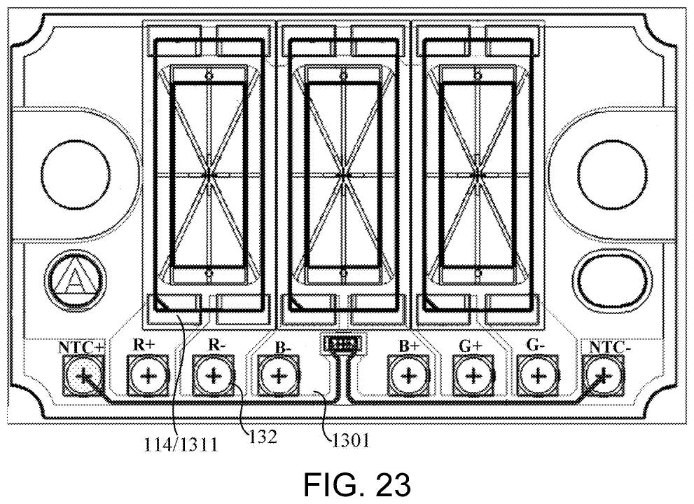

FIG. 23 is a schematic top structure diagram of still another laser according to some embodiments of the present application. Referring to FIG. 23, exemplarily, three types of light-emitting chips of different colors in the same light-emitting unit are respectively arranged in three different packages, that is, each package is provided with the light-emitting chips 113 of one color, and the arrangement direction of the packages is the same as the arrangement direction of the connection pads 132. On the side of the package facing the mounting substrate 130, two bottom pads 114 arranged side by side are provided on the side of each package adjacent to the connection pads 132. The two bottom pads 114 under each package are connected to one group of connection pads 132 via the transition pads 1311 and the in-substrate connection wires 1301 respectively. Specifically, the conductive pattern of the connection pattern of the mounting substrate 130 includes three repeating units corresponding to the packages, a side of each repeating unit close to the connection pad 132 includes two transition pads 1311 arranged side by side, and each transition pad 1311 is electrically connected to the corresponding connection pad 132 via the in-substrate connection wire 1301. The transition pads 1311 are connected to the bottom pads 114 of the package in a one-to-one correspondence manner, and the bottom pads 114 are electrically connected to the light-emitting chips 113 in the package via the side wall connection wires 117 in the package, so that the light-emitting chips 113 are electrically connected to the corresponding connection pads 132.

Exemplarily, as shown in FIG. 23, the left package is configured to package the red light-emitting chip, and the corresponding two bottom pads 114 are respectively connected to the red positive polarity pad R+ and the red negative polarity pad R− via the transition pads 1311 and the in-substrate connection wires 1301. The middle package is configured to package the blue light-emitting chip, and the two corresponding bottom pads 114 are respectively connected to the blue negative polarity pad B− and the blue positive polarity pad B+ via the transition pads 1311 and the in-substrate connection wires 1301. The right package is configured to package the green light-emitting chip, and the two corresponding bottom pads 114 are respectively connected to the green positive polarity pad G+ and the green negative polarity pad G− via the transition pads 1311 and the in-substrate connection wires 1301.

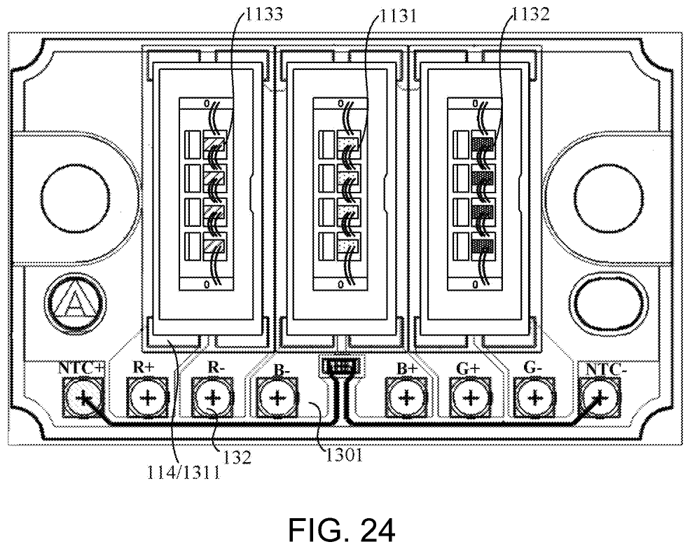

FIG. 24 is a schematic top plane structure diagram of still another laser according to some embodiments of the present application. Referring to FIG. 24, exemplarily, the laser includes three packages, the light-emitting chips 113 of each color are independently packaged in one package, that is, the light-emitting colors of the light-emitting chips 113 in each package are the same, and the light-emitting chips 113 in each package are connected in series to form a circuit. That is, all the first-type light-emitting chips 1131 are arranged in the same package, and all the first-type light-emitting chips 1131 are connected in series; all the second-type light-emitting chips 1132 are arranged in the same package, and all the second-type light-emitting chips are connected in series; all the third-type light-emitting chips 1133 are arranged in the same package, and all the third-type light-emitting chips 1133 are connected in series. The connection pads 132 are located on the same side of the three packages, and the connection pads 132 and the packages are arranged in the same direction. Two bottom pads 114 are arranged on the side of each package close to the connection pads 132, and the arrangement direction of the two bottom pads 114 is the same as that of the connection pads 132. The two bottom pads 114 of each package are electrically connected to the corresponding group of connection pads 132.

FIG. 25 is a schematic surface structure diagram of the side of the package facing the mounting substrate in still another laser according to some embodiments of the present application. Referring to FIG. 25, exemplarily, the conductive pattern at the bottom of each package includes four bottom pads 114 and one connection layer 115 (each not connected to the other), the bottom pads 114 being located at the four corners of the rectangular package and the connection layer 115 being located at the center of the package.

In other possible implementations, the bottom pads 114 may be arranged on both the side of the package close to the connection pad 132 and the side away from the connection pad 132, and correspondingly, the transition pads 1311 may be arranged on both the side of the mounting substrate 130 close to the connection pad 132 and the side away from the connection pad 132. Under the condition that the distance between the positioning hole and the package and the distance between the packages satisfy the minimum wiring width, the in-substrate connection wire 1301 may be arranged between the positioning hole and the package and/or between the packages to electrically connect the transition pad 1311 on the side away from the connection pad 132 and the transition pad 1311 on the side close to the connection pad 132, so as to increase the wiring width and thus reduce the resistance.

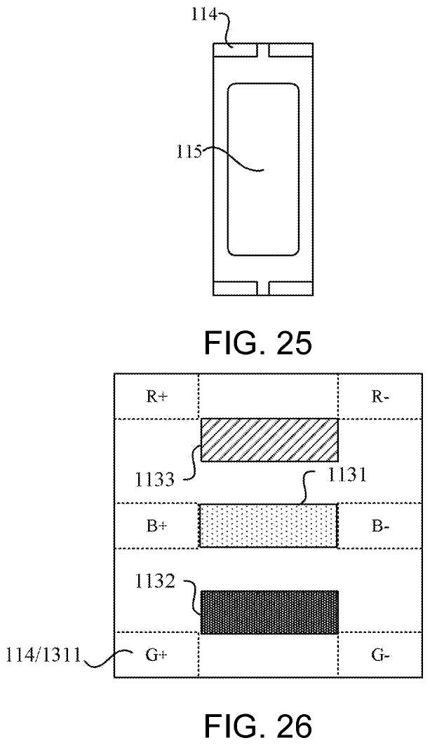

FIG. 26 is a schematic structural diagram of the package of still another laser according to some embodiments of the present application. Referring to FIG. 26, exemplarily, the light-emitting chips 113 of three colors of a single light-emitting unit (i.e., the first-type light-emitting chip 1131, the second-type light-emitting chip 1132 and the third-type light-emitting chip 1133) are packaged in the same package, and in this package, the light-emitting chips of each color are connected to the corresponding bottom pads, so as to be connected to the corresponding connection pads on the mounting substrate.

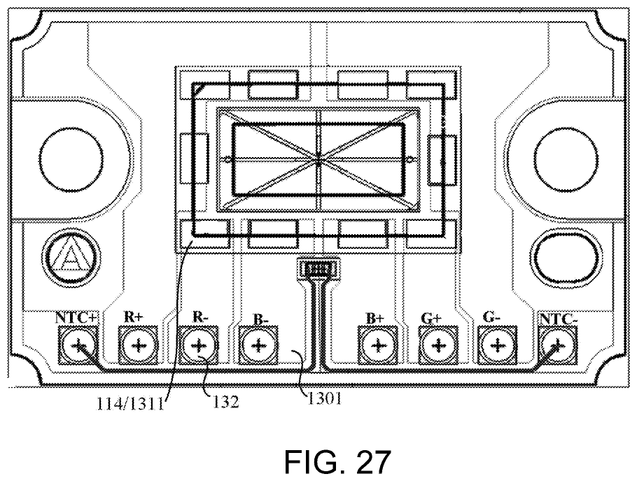

FIG. 27 is a schematic top structure diagram of still another laser according to some embodiments of the present application. Referring to FIG. 27, exemplarily, in the laser, light-emitting chips 113 of three colors are arranged in one package. The package includes four bottom pads 114 arranged side by side at least on a first side near the connection pad 132, and further includes one bottom pad 114 on each of a second side and a third side that are adjacent to the first side, and the second side is opposite to the third side. The six bottom pads 114 of the package are correspondingly connected to the three groups of connection pads 132 respectively. As shown in FIG. 27, the mounting substrate 130 includes transition pads 1311 and in-substrate connection wires 1301, the side of the conductive pattern of the connection pattern near the connection pad 132 (corresponding to the first side of the package) includes four transition pads 1311, the left and right sides (corresponding to the second and third sides of the package) each include one transition pad 1311, and the six transition pads 1311 are connected to the six bottom pads 114 in a one-to-one correspondence manner. The transition pads 1311 are electrically connected to the corresponding connection pads 132 via the in-substrate connection wires 1301, so that the six bottom pads 114 are correspondingly connected to the six connection pads 132. The specific connection relationship is as follows: the bottom pad 114 on the second side (left side for example) is electrically connected to the red positive polarity pad R+ via the transition pad 1311 and the in-substrate connection wire 1301, optionally, three transition pads 1311 may be electrically connected to the red positive polarity pad R+ via the same in-substrate connection wire 1301; the first bottom pad 114 at the left end of the first side is electrically connected to the red negative polarity pad R− via the transition pad 1311 and the in-substrate connection wire 1301; the second bottom pad 114 at the left end of the first side is electrically connected to the blue negative polarity pad B− via the transition pad 1311 and the in-substrate connection wire 1301; the second bottom pad 114 at the right end of the first side is electrically connected to the blue positive polarity pad B+ via the transition pad 1311 and the in-substrate connection wire 1301; the first bottom pad 114 at the right end of the first side is electrically connected to the green positive polarity pad G+ via the transition pad 1311 and the in-substrate connection wire 1301, and the bottom pad on the third side (right side for example) is electrically connected to the green negative polarity pad G− via the transition pad 1311 and the in-substrate connection wire 1301, optionally, three transition pads 1311 may be electrically connected to the green negative polarity pad G− via the same in-substrate connection wire 1301.

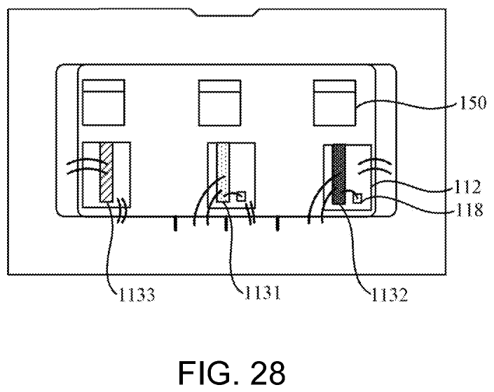

FIG. 28 is a schematic top plane structure diagram of the package of still another laser according to some embodiments of the present application. Referring to FIG. 28, exemplarily, the first-type light-emitting chip 1131, the second-type light-emitting chip 1132 and the third-type light-emitting chip 1133 are located in the same package. The light-emitting chips 113 of three colors are arranged in a line from left to right, and are connected to the side wall of the package via metal wires made of gold (Au) respectively, so as to be electrically connected to the side wall connection wires. For the case where the third-type light-emitting chip 1133 is a red light-emitting chip, the first-type light-emitting chip 1131 is a blue light-emitting chip, and the second-type light-emitting chip 1132 is a green light-emitting chip, antistatic apparatuses 118 need to be arranged on the blue light-emitting chip and the green light-emitting chip, and since the antistatic capability of the material of the red light-emitting chip is strong, the red light-emitting chip is not equipped with the antistatic apparatus 118. The laser further includes a reflecting component 150 and a heat sink 112, the light-emitting chip 113 and the antistatic apparatus 118 are arranged on the heat sink 112, the reflecting component 150 is located on an exit side of the light-emitting chip 113, and a reflecting surface of the reflecting component 150 is aligned and matched with the light-emitting chip 113. The light-emitting chips 113 may be arranged in one-to-one correspondence with the heat sinks 112, or a plurality of light-emitting chips 113 with the same light-emitting color may be arranged on the same heat sink 112, which is not limited herein.

In other possible implementations, the red positive polarity pad R+ may also be connected to three adjacent transition pads 1311 via the in-substrate connection wire 1301. Similarly, the green negative polarity pad G− may be connected to three adjacent transition pads 1311 via the in-substrate connection wire 1301, and the configuration may be performed according to the relative positions and sizes of the mounting substrate 130, the package, and the positioning hole 135, which is not limited herein.

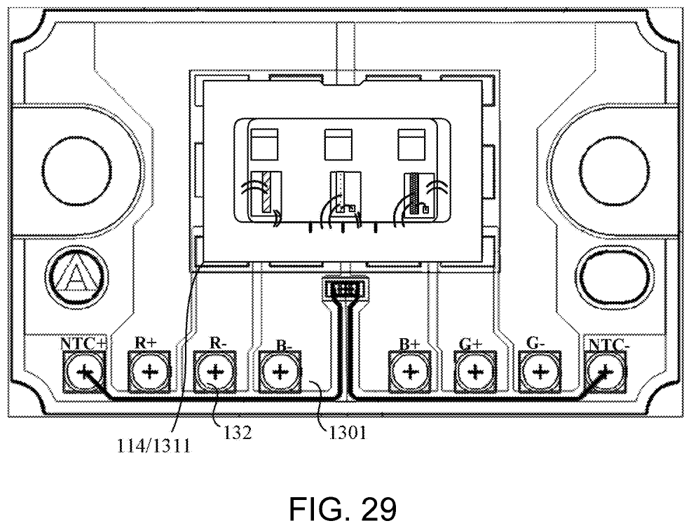

FIG. 29 is a schematic top plane structure diagram of still another laser according to some embodiments of the present application. Referring to FIG. 29, exemplarily, the side of the package near the connection pad 132 is the first side, and the second side and the third side are respectively located on left and right sides and adjacent to the first side. Four bottom pads 114 are arranged side by side on the first side of the package, one bottom pad 114 is arranged on the second side, and one bottom pad 114 is arranged on the third side.

As shown in FIG. 29, the mounting substrate 130 includes transition pads 1311 and in-substrate connection wires 1301. The side of the conductive pattern of the connection pattern near the connection pad 132 (corresponding to the first side of the package) includes four transition pads 1311, the left and right sides (corresponding to the second and third sides of the package) each include one transition pad 1311, and the six transition pads 1311 are connected to the six bottom pads 114 in a one-to-one correspondence manner. The transition pads 1311 are electrically connected to the corresponding connection pads 132 via the in-substrate connection wires 1301, so that the six bottom pads 114 are correspondingly connected to the six connection pads 132. The specific connection relationship is as follows: the bottom pad 114 on the second side (left side for example) is electrically connected to the red positive polarity pad R+ via the transition pad 1311 and the in-substrate connection wire 1301; optionally, three transition pads 1311 may be electrically connected to the red positive polarity pad R+ via the same in-substrate connection wire 1301; the first bottom pad 114 at the left end of the first side is electrically connected to the red negative polarity pad R− via the transition pad 1311 and the in-substrate connection wire 1301; the second bottom pad 114 at the left end of the first side is electrically connected to the blue negative polarity pad B− via the transition pad 1311 and the in-substrate connection wire 1301; the second bottom pad 114 at the right end of the first side is electrically connected to the blue positive polarity pad B+ via the transition pad 1311 and the in-substrate connection wire 1301; the first bottom pad 114 at the right end of the first side is electrically connected to the green positive polarity pad G+ via the transition pad 1311 and the in-substrate connection wire 1301, and the bottom pad on the third side (right side for example) is electrically connected to the green negative polarity pad G− via the transition pad 1311 and the in-substrate connection wire 1301; optionally, three transition pads 1311 may be electrically connected to the green negative polarity pad G− via the same in-substrate connection wire 1301.

In other possible implementations, the red positive polarity pad R+ may also be connected to three adjacent transition pads 1311 via the in-substrate connection wire 1301. Similarly, the green negative polarity pad G− may be connected to three adjacent transition pads 1311 via the in-substrate connection wire 1301, and the configuration may be performed according to the relative positions and sizes of the mounting substrate 130, the package, and the positioning hole 135, which is not limited herein.

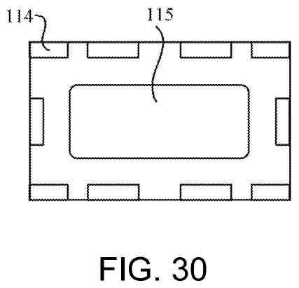

In some possible implementations, as shown in FIG. 29 and FIG. 30, the package further includes a fourth side arranged opposite to the first side, and the fourth side includes four bottom pads 114 arranged side by side. Two of the bottom pads 114 on the fourth side are connected together by the same in-substrate connection wire 1301, and the other two bottom pads 114 are connected together by the same in-substrate connection wire 1301.

In this embodiment, the fourth side of the package is the side away from the connection pad 132, and is also provided with four bottom pads 114. Correspondingly, as shown in FIG. 27, four transition pads 1311 are also arranged on the side of the connection pattern 13 away from the connection pad 132, and the four transition pads 1311 are connected to the four bottom pads on the fourth side of the package in a one-to-one correspondence manner. The two transition pads 1311 on the left side are electrically connected to one nearby transition pad 1311 on the left side of the connection pattern 13, so that the three transition pads 1311 are electrically connected to the red positive polarity pad R+ via the same in-substrate connection wire 1301, realizing that two bottom pads 114 on the fourth side of the package are connected to the bottom pad 114 on the second side through the same in-substrate connection wire 1301. The two transition pads 1311 on the right side are connected to one nearby transition pad 1311 on the right side of the connection pattern 13, so that the three transition pads 1311 are electrically connected to the green negative polarity pad G− via the same in-substrate connection wire 1301. With this arrangement, each of the red positive polarity pad R+ and the green negative polarity pad G− is connected to three transition pads 1311, realizing that two bottom pads 114 on the fourth side of the package are connected to the bottom pad 114 on the third side via the same in-substrate connection wire 1301. With this arrangement, the width of the in-substrate connection wire 1301 is increased, which is conducive to reducing the resistance.

It should be noted that FIG. 27 and FIG. 29 only exemplarily show the case that the transition pads 1311 on the side of the mounting substrate 130 away from the connection pad 132 are divided into two groups, and each group includes two transition pads 1311, which does not constitute a limitation on the laser according to the embodiment of the present application.

FIG. 30 is a schematic diagram of a surface structure of the side of the package facing the mounting substrate in still another laser according to some embodiments of the present application. Referring to FIG. 30, exemplarily, the conductive pattern at the bottom of the package includes ten bottom pads 114 and one connection layer 115 (each not connected to the other). The ten bottom pads 114 are located around the rectangular package (four bottom pads 114 are arranged on the first side, one bottom pad 114 is arranged on each of the second side and the third side, and four bottom pads 114 are arranged on the fourth side), and the connection layer 115 is located at the center of the package.

In some possible implementations, in the plane of the mounting substrate 130, the length of the connection pad 132 in the arrangement direction of the connection pads 132 ranges from 1.3 mm to 1.7 mm, and along the arrangement direction of the connection pads 132, the distance between adjacent connection pads 132 ranges from 0.8 mm to 1.2 mm.

In some possible implementations, in the plane of the mounting substrate 130, the length of the long side of the transition pad 1311 ranges from 1.1 mm to 1.5 mm, and the length of the short side ranges from 0.4 mm to 0.8 mm. Along the arrangement direction of the transition pads 1311, the distance between adjacent transition pads 1311 ranges from 0.1 mm to 0.5 mm.

In the present application, the size (including the length and the width) of the package is not limited, and the size of the package may be set according to the requirement of the laser. For example, the size of the package is 10.6 mm×6.4 mm.

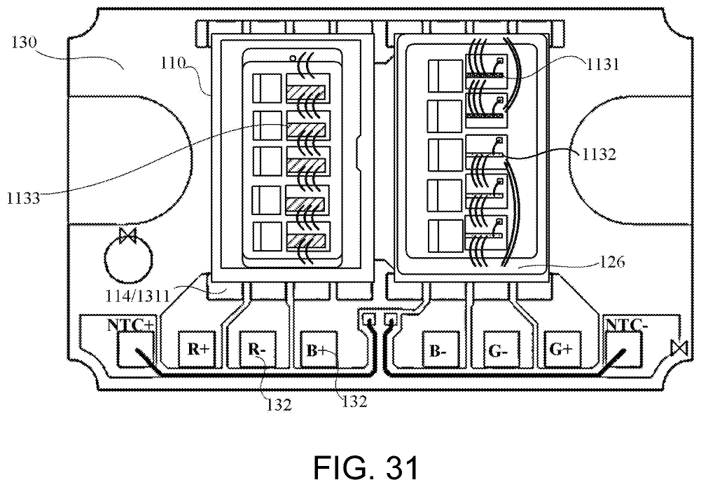

FIG. 31 is a schematic top plane structure diagram of still another laser according to some embodiments of the present application. FIG. 31 differs from the example shown in FIG. 11 in that the arrangement positions of the first-type light-emitting chip 1131, the second-type light-emitting chip 1132, and the third-type light-emitting chip 1133 in the package are different. In FIG. 31, in the second package 120, the upper two serially connected light-emitting chips are the first-type light-emitting chips 1131, i.e., blue light-emitting chips, and the lower three serially connected light-emitting chips are the second-type light-emitting chips 1132, i.e., green light-emitting chips. In addition, in this example, the third-type light-emitting chip 1133 is mounted to the lower region of the corresponding heat sink (i.e., the region of the corresponding heat sink close to the group of connection pads 132 corresponding to the third-type light-emitting chip 1133), and the metal wire corresponding to the third-type light-emitting chip 1133 is arranged on the upper region (i.e., the region opposite to the lower region, that is, the region of the corresponding heat sink away from the connection pads corresponding to the third-type light-emitting chip 1133) of the heat sink therefor as shown in the drawing, so that the third-type light-emitting chip 1133 and the metal wire corresponding thereto are arranged side by side along the length direction of the heat sink and are respectively located on different regions along the width direction of the heat sink. In this case, the heat sink corresponding to the third-type light-emitting chip 1133 is in a long strip shape, and the light-emitting chip and the corresponding metal wire are distributed on the opposite regions of the long strip-shaped heat sink, so that on the one hand, heat conduction can be guaranteed through the change of the area of the long strip-shaped heat sink, and on the other hand, the size in the width direction of the heat sink can be reduced, and therefore, more light-emitting chips can be arranged in a limited internal space of the package. FIG. 11 and FIG. 31 are also different in that the metal wires of the light-emitting chips of different colors in the second package are different, the corresponding transition pads 1311 on the mounting substrate 130 are different, and the in-substrate connection wires 1301 connecting the transition pads 1311 on the mounting substrate 130 are also different.

In some examples, as shown in FIG. 11 and FIG. 31, one temperature detecting component NTC (e.g., the thermistor 134) may be provided, arranged on the mounting substrate 130, located between the first package and the second packages, and configured to measure the temperature rise of the region between the two packages to reflect temperature rise data of the light-emitting chips in the two packages.

In some implementations, two electrodes of the temperature detecting component and the plurality of electrodes of the light-emitting chips are arranged together, and the two electrodes of the temperature detecting component are located on both sides of the plurality of electrodes of the plurality of light-emitting chips, respectively. As shown in FIG. 11, the temperature detecting component NTC is further provided with corresponding connection pads 132N on the mounting substrate 130. There are two connection pads 132N respectively located on both sides of the corresponding connection pads of the plurality of light-emitting chips. In this way, a wiring path of the temperature detecting component is long, but the lengths of wiring paths of different light-emitting chips can be shortened, thereby improving the power supply reliability.

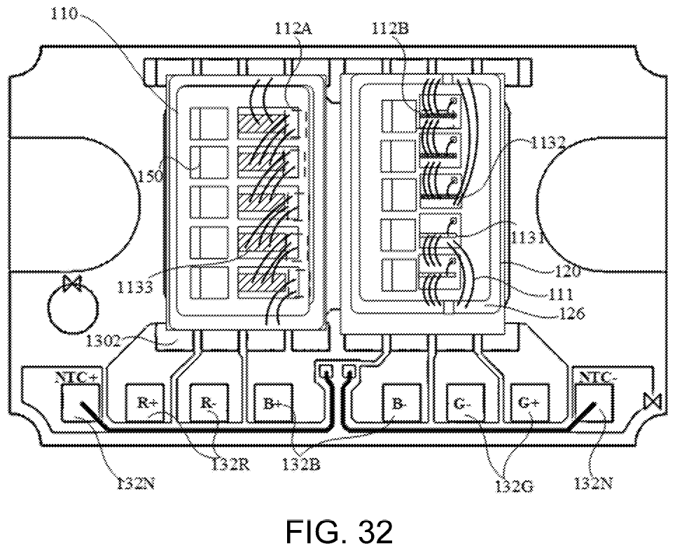

FIG. 32 is a schematic top plane structure diagram of still another laser according to some embodiments of the present application. In some embodiments, referring to FIG. 32, the laser 10 includes a first package 110 and a second package 120. The structures of the first package 110 and the second package 120, as well as electrical connections between the packages and the mounting substrate, may refer to the corresponding related descriptions of the laser shown in FIG. 11. In addition, the electrical connection relationship between the second package 120 and the mounting substrate in the example of FIG. 32 may refer to the related description in the example shown in FIG. 4, which is not repeated. Compared with the laser illustrated in FIG. 11, in the example shown in FIG. 32, the connection manner between the metal wires of the plurality of red light-emitting chips in the first package 110 and the heat sinks is different from that in the example of FIG. 11.

Referring to FIG. 32, the second package 120 includes first-type light-emitting chips 1131 and second-type light-emitting chips 1132, and in the process in which the plurality of first-type light-emitting chips 1131 and the plurality of second-type light-emitting chips 1132 are respectively connected in series, the light-emitting chip is connected to a side portion of the heat sink of the adjacent light-emitting chip (for example, a side region 112B of the heat sink shown in FIG. 32) through the metal wire. This connection manner requires sufficient space in the width direction of the heat sink, so that a position for wire bonding is reserved in the side region of the heat sink, allowing the metal wires of the adjacent light-emitting chips to be connected thereto. The connection manner provided by this example can provide a better heat conduction radiation path for the light-emitting chip, because the wider the heat sink is, the longer the heat conduction path for the two outward sides of the light-emitting chip is, but the size of the package in the length direction is generally increased.

The first package 110 includes a plurality of third-type light-emitting chips, and all the third-type light-emitting chips are connected in series. Unlike the second package 120, the metal wire of the third-type light-emitting chip is connected to a rear end of the heat sink 112 of the adjacent third-type light-emitting chip, such as a rear end region 112A of the heat sink shown in FIG. 32. It should be noted that the front end and the rear end of the heat sink are defined relative to the exit surface of the light-emitting chip or relative to the position where the reflecting component 150 is arranged. On the heat sink, a heat sink region near the exit surface of the light-emitting chip 113 or a heat sink region near the reflecting component 150 is referred to as the front end of the heat sink, and on the heat sink, a heat sink region away from the exit surface of the light-emitting chip or a heat sink region away from the reflecting component is referred to as the rear end of the heat sink. In the connection manner provided by the present example, the heat sink has an elongated strip shape, that is, the width is smaller that of the heat sink in the first package 110 in the example shown in FIG. 31. By providing the elongated strip-shaped heat sink, a certain heat conduction area of the heat sink can be provided, and when the same number of light-emitting chips are arranged, the size can be reduced correspondingly along the arrangement direction of the light-emitting chips, i.e., the length direction of the package. In some examples, the reduction of the size of the package in the length direction may slightly increase or not increase the size of the package in the width direction. In some examples, the elongated strip-shaped heat sink structure can also ensure a reasonable distance between the light-emitting chips without changing the size of the package, so that more light-emitting chips can be arranged in a limited space.

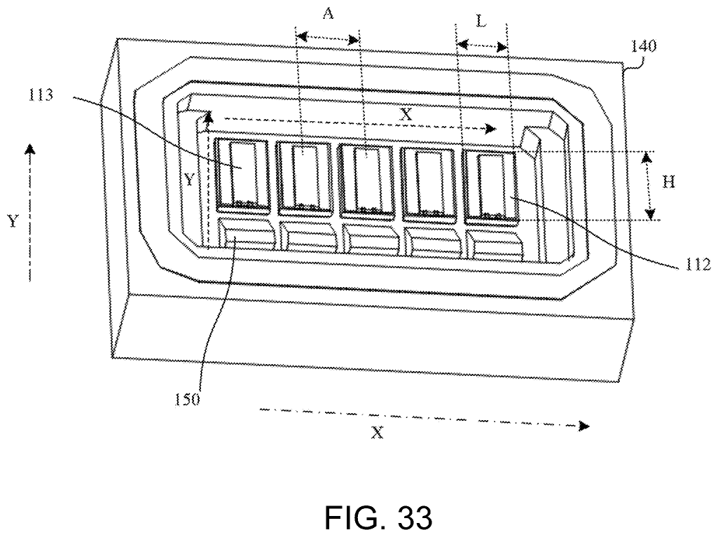

FIG. 33 is a schematic internal structure diagram of the package in the laser according to some embodiments of the present application. Referring to FIG. 33, for better illustration, H represents the width of the heat sink 112, and L represents the length of the heat sink 112. A is the distance between central axes of two adjacent light-emitting chips, and may also be regarded as the distance between two adjacent light-emitting chips.

In this example, the outer contour of the side wall 140 of the package is rectangular. In some examples, the package has a length of about 8.5 mm to 9.0 mm, a width of about 5.9 mm to 6.9 mm, and a wall thickness of about 1 mm.

The side wall 140 of the package has a certain thickness, and a projection of an inner space defined by the side wall 140 of the package is also approximately rectangular, and hereinafter is referred to as an inner rectangle. The length of the inner rectangle in the long side direction is about 5.5 mm, the length of the inner rectangle in the short side direction is about 3.5 mm to 4.5 mm, and the inner rectangle is approximately similar in shape to the outer contour rectangle of the package.

Along the length direction of the side wall 140 of the package, or along the length direction of the inner rectangle of the package, for example, the X direction shown in FIG. 33, a plurality of heat sinks 112 are arranged in a row, and a gap is formed between every two adjacent heat sinks 112.

In some examples, the distance between the plurality of heat sinks is 1.0 mm to 1.25 mm. Taking one of the heat sinks as an example for explanation, the width H of the heat sink is 0.85 mm-0.95 mm.

The width of the heat sink 112 is related to the size of the light-emitting chip 113 and the requirements of a processing technology. In some examples, the width of the light-emitting chip 113 on the heat sink 112 is about 500 um, and the width of the AuSn solder layer for soldering the light-emitting chip and the heat sink is about 550 um to 600 um. In some examples, a Zener diode is also required to be arranged on the heat sink as the above-mentioned antistatic apparatus, the Zener diode and the light-emitting chip are arranged side by side, and therefore, the width of the heat sink 112 is at least larger than the widths of the light-emitting chip and the Zener diode.

According to the above description, the reflecting component 150 is further arranged on one side of the light-emitting chip 113, and the light-emitting chip 113 and the reflecting component 150 are arranged along the width direction of the package, or the short side direction of the inner rectangle of the package.

The length direction of the heat sink 112 is parallel to the width direction of the side wall 140 of the package or the short side direction (illustrated Y direction) of the inner rectangle of the package.

In some examples, the ratio of the length of the heat sink 112 to the width of the heat sink 112 ranges from 1 to 3.5.

In some embodiments, the ratio of the length of the heat sink 112 to the width of the heat sink 112 ranges from 1.5 to 3.5. In an exemplary implementation, L=2.1 mm and H=0.65 mm, so the ratio of the length of the heat sink 112 to the width of the heat sink 112 is 3.2, and the heat sink is in an elongated strip shape, which is suitable for the case without the Zener diode, such as the red light-emitting chip, or for the case where the Zener diode and the light-emitting chip are arranged along the length direction of the heat sink. With this arrangement, on the premise of the same space in the package and the fixed distance, the smaller the width of the heat sink is, the greater the number of the corresponding light-emitting chips that can be arranged is, the higher the density of the light-emitting chips is, the higher the accommodation rate of light-emitting elements in the package is, and the higher the light power is. However, the higher the arrangement density of the light-emitting chips, the higher the requirement for heat dissipation. Thus, in the above case, the heat sink may be made of a material with a higher thermal conductivity coefficient, such as diamond-copper. Alternatively, an integrated configuration of the package bottom plate and the heat sink may be considered, using the same material, so as to reduce the thermal resistance caused by a combination of different materials.

In another exemplary implementation, L=1.7 mm and H=1.1 mm, so the ratio of the length of the heat sink 112 to the width of the heat sink 112 is approximately 1.5, and the shape of the heat sink is approximate to a square, which facilitates arranging the Zener diode and the light-emitting chip side by side. Since heat conduction of the light-emitting chip is downward and outward in a plurality of directions, the heat conduction of the light-emitting chip is better equalized in all directions when the shape of the heat sink is approximate to a centrosymmetric pattern. For example, in the above example, the sizes of the heat sink in the long side direction and the short side direction are equivalent, for example, the shape is a square, or the shape of the heat sink is a circle, or the shape of the heat sink is a polygon. In the present example, in order to improve the arrangement density of the light-emitting chips, in the case where the width of the heat sink is larger than that of the previous example, it may be considered to reduce the distance between the adjacent heat sinks, for example, in the present example, the distance between the heat sinks may be 1.0 mm, which also helps increases the number of the light-emitting chips accommodated under the same space in the package.

With the above embodiments, a high-power laser light-emitting assembly may be provided.

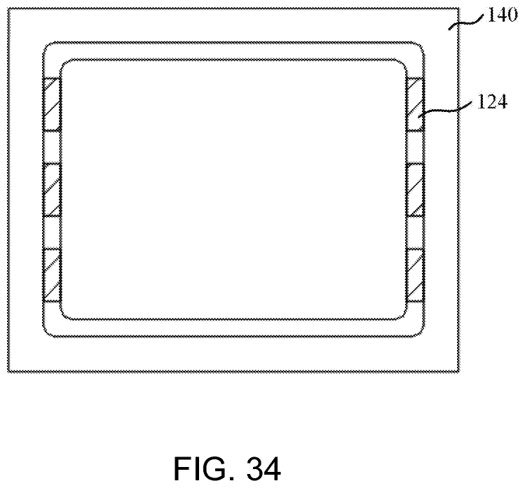

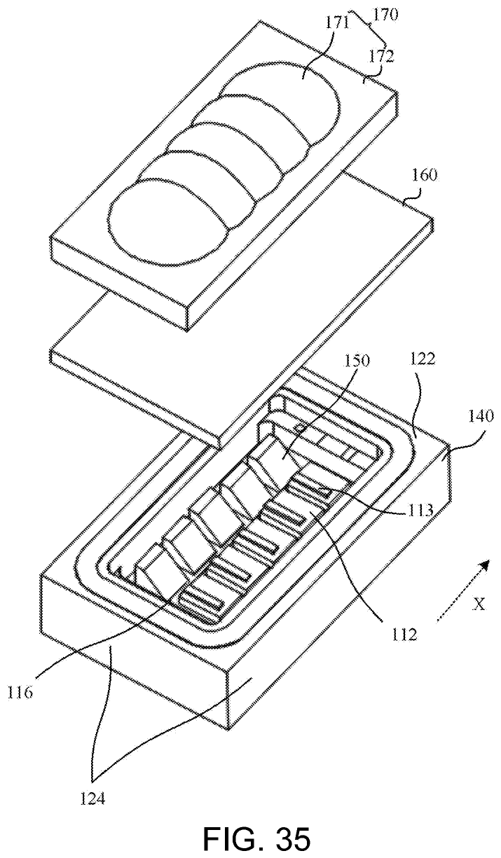

FIG. 34 is a schematic sectional structure diagram of a package in a laser according to some embodiments of the present application, and FIG. 35 is a schematic exploded structure diagram of the package in the laser according to some embodiments of the present application.

As shown in FIG. 35, the laser 10 further includes a lens assembly 170 and a reflecting component 150. The side wall 140 of the package is ring-shaped and surrounds the plurality of heat sinks 112, the plurality of light-emitting chips 113, and the plurality of reflecting components 150. The lens assembly 170 is located on a side of the side wall 140 of the package away from the mounting substrate 130. An upper portion of the side wall 140 of the package is connected to the light-transmitting component 160 to form a sealed space.

The plurality of light-emitting chips 113 are in one-to-one correspondence to the plurality of reflecting components 150, and each reflecting component 150 is located on the exit side of the corresponding light-emitting chip 113. The reflecting component 150 is configured to reflect light emitted by the corresponding light-emitting chip 113 to the lens assembly 170 corresponding to the light-emitting chip 113, so that the lens assembly 170 collimates the light. The reflecting component 150 may be a reflecting prism or a reflecting mirror having a support structure. The position of a reflection point of one reflecting component 150 corresponds to the center of a corresponding collimating lens in the lens assembly 170. In this example, the plurality of light-emitting chips 113 are in one-to-one correspondence to the plurality of reflecting components 150, and the plurality of reflecting components 150 are in one-to-one correspondence to a plurality of collimating lens units in the lens assembly 170, so that the number of the light-emitting chips 113 is the same as the number of the reflecting components 150 and the number of the collimating lens units in the lens assembly 170.

Some embodiments of the package are described below with reference to the drawings.

FIG. 34 is a sectional view of the package as viewed from above, and as shown in FIG. 34, the side wall 140 of the package has a thickness and a plurality of conductive regions 124 are formed inside the package.

Referring to FIG. 4 and FIG. 5, a plurality of packages are arranged on the mounting substrate 130.

Referring to FIG. 6, for each package, a light-emitting assembly formed by the heat sink and the light-emitting chip, the lens assembly 170, and the reflecting component 150 are arranged in an accommodating space. The package has a certain height, and the package is connected to the package bottom plate and the light-transmitting component respectively to form the accommodating space.

In an implementation, referring to FIG. 35, the side wall 140 of the package has an upper surface 122 and a plurality of outer sides. In a top view, the outer contour of the side wall 140 of the package is rectangular, and the inner contour of the side wall 140 of the package is also rectangular.

In some embodiments, the side wall 140 of the package is made of a ceramic material. The material of the side wall 140 of the package is not limited to the ceramic, and may be metal or a composite containing metal as a main material. For example, aluminum nitride, silicon nitride, aluminum oxide, or silicon carbide may be used in the ceramic as the main material of the side wall 140 of the package.

The side wall 140 of the package may also be made of a metallic material such as a composite of copper, aluminum and iron, and copper molybdenum, a copper-diamond composite, copper tungsten, or the like, may be used as the main material of the side wall 140 of the package.

Here, the main material refers to the material that accounts for the largest proportion by mass or volume in the formation of a target product.

In this example, the side wall 140 of the package is made of the ceramic material, and as shown in FIG. 35, a conductive region is formed in an inner wall of the side wall 140 of the package, and the light-emitting chip 113 is electrically connected to the conductive region 124 of the side wall 140 of the package.

In some other embodiments, the material of the side wall 140 of the package may include one or more of oxygen-free copper and a ceramic material. When the mounting substrate 130 is a PCB including oxygen-free copper therein, the mounting substrate 130 may assist the heat sink 112 in conducting the heat generated by the light-emitting chip 113 due to the large thermal conductivity coefficient of the oxygen-free copper.

In some implementations, the number of the plurality of light-emitting chips 113 is at least five. The plurality of light-emitting chips 113 are arranged along a first direction within the side wall 140 of the package, and the first direction is the length direction of the side wall 140 of the package.

It should be noted that such an arrangement not only realizes miniaturization of the apparatus, but also improves the thermal management efficiency, optimizes the circuit design and arrangement, reduces the production cost, and improves the performance and reliability of the apparatus.

The first direction may be the length direction of the side wall 140 of the package, and the plurality of light-emitting chips 113 may be arranged at intervals along the length direction of the side wall 140 of the package,

As shown in FIG. 35, X represents the first direction, i.e., the length direction of the side wall 140 of the package.

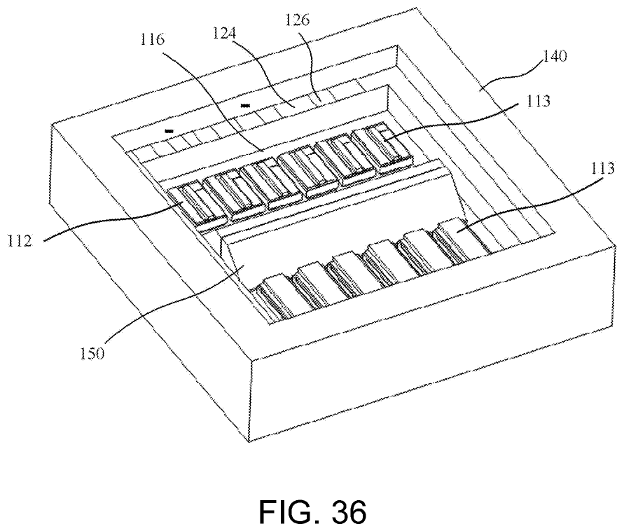

FIG. 36 is a schematic internal structure diagram of another package in the laser according to some embodiments of the present application.

As shown in FIG. 36, the side wall 140 of the package has a step portion 126, conductive regions 124 are arranged on the step portion 126. The plurality of conductive regions 124 are on a part of a surface region of the step portion 126, and are isolated and disconnected by insulating regions. The conductive region 124 is configured to connect the light-emitting chip 113 and conductive wiring in the side wall 140 of the package.

In some embodiments, the side wall 140 of the package has one or more step portions 126, and the conductive regions 124 are arranged on the one or more step portions 126.

As shown in FIG. 36, the step portions 126 may be formed along all inner side wall of the side wall 140 of the package and protrude towards the inner space defined by the side wall 140 of the package. The step portions 126 may be located on only one inner side wall, or two opposite inner side walls of the package, or two adjacent inner side walls.

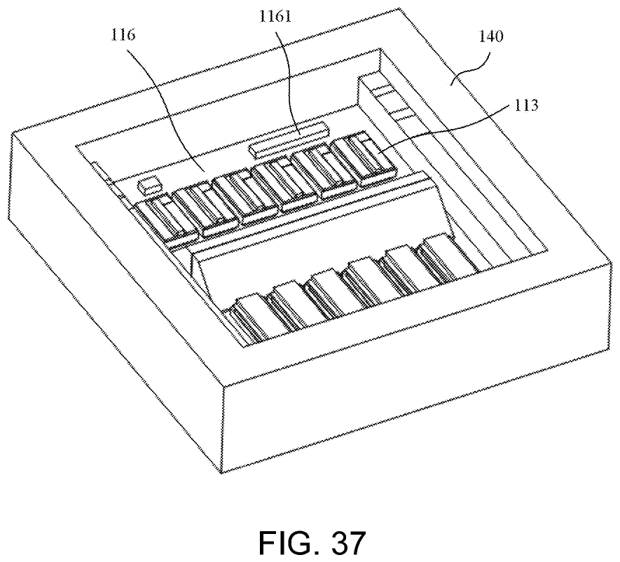

FIG. 37 is a schematic internal structure diagram of still another package in the laser according to some embodiments of the present application.

As shown in FIG. 37, a transition stage 1161 is further provided. The transition stage 1161 is located on the package bottom plate 116 between the side wall 140 of the package and the light-emitting chip 113, and the transition stage 1161 is provided with a conductive region for connecting the metal wire of the light-emitting chip 113 and a wiring conductive region in the side wall 140 of the package.

Through the transition of the transition stage 1161, the problem of breakage of the metal wire of the light-emitting chip can be reduced, and the difficulty of wire bonding is lowered. The metal wire of the light-emitting chip may be first connected to the transition pad and then connected to the conductive region in the wall of the package via the transition pad, thus realizing the connection between the light-emitting chip and the conductive region of the package.

In some embodiments, multiple transition stages 1161 may be provided, so as to provide a plurality of transition paths for the metal wires, thereby lowering the difficulty of wire bonding.

The red light-emitting chip is taken as an example and described below with reference to the accompanying drawings.

In this example, the ratio of the length of the heat sink 112 to the width of the heat sink 112 corresponding to the red light-emitting chip ranges from 1 to 1.7.

When the light-emitting chip 113 is a red light-emitting chip, the light-emitting chip 113 transfers heat downwards at an angle of θ from an edge angle, that is, θ is an angle of heat conduction from the light-emitting chip towards the heat sink. The width L of the heat sink is larger than or equal to (L0+2 tan θ×D), where L0 is the width of the light-emitting chip, and D is the thickness of the heat sink. The thickness of the heat sink 112 is generally about 300 um, the width of the light-emitting chip 113 is about 0.5 mm, and when heat radiation or heat transfer is performed at an angle of 45°, the width L of the heat sink is about 1.1 mm. The above arrangement enables rapid heat conduction of the heat generated in the light-emitting process of the light-emitting chip, thereby reducing heat accumulation.

In addition, in this example, the length H of the heat sink is equal to Ho×K1+K2, where Ho is the length of the light-emitting chip which ranges from 1.2 mm to 1.5 mm, and K1 is an accommodation coefficient which may range from 1.06 to 1.12; K2 is a constant which ranges from 0.05 to 0.1. In an implementation, Ho=1.5 mm, K1=1.067, and K2=0.05 mm, so that the length H of the heat sink is 1.65 mm.

In some implementations, the ratio of the width of one heat sink 112 to the width of the side wall 140 of the package ranges from 0.05 to 0.2. It should be noted that here, the width of the package refers to the length of the short side of the outer contour rectangle of the package.

The ratio of the sum of the widths of all the heat sinks 112 to the width of the side wall 140 of the package ranges from 0.4 to 0.8.

Through this arrangement, the accommodation capacity for the heat sinks 112 in the inner space of the side wall 140 of the package can be increased, which is conducive to arranging more light-emitting chips.

In addition, since the heat conduction performance of the heat sink is generally better than that of the package bottom plate and the package, the increase of the accommodation capacity for the heat sinks in the package is also conducive to accelerating heat conduction in the limited package space.

In some implementations, the width of the heat sink 112 is 1.05 mm, the width of the side wall 140 of the package is 8.5 mm, and the ratio of the width of the heat sink 112 to the width of the side wall 140 of the package is 0.12.

In some other implementations, the width of the heat sink 112 is 0.8 mm, and the ratio of the width of the heat sink 112 to the width of the side wall 140 of the package is 0.09.

The total width of the heat sinks 112 may be defined according to the number of the light-emitting chips 113 actually mounted.

In some implementations, the ratio of the width of one heat sink 112 to the width of the side wall 140 of the package ranges from 0.07 to 0.12.

In some implementations, the ratio of the width of one heat sink 112 to the width of the side wall 140 of the package ranges from 0.1 to 0.15.

In some examples, the width of the side wall 140 of the package is 8.5 mm, and the width of the heat sink 112 ranges from 0.6 mm to 1 mm, so that five light-emitting chips 113 can be mounted. In this case, the ratio of the width of one heat sink 112 to the width of the side wall 140 of the package is between 0.07 and 0.12.

Theoretically, as a solution, when the width of the heat sink 112 increases, the width of the side wall 140 of the package correspondingly increases. It is be conducive to the heat dissipation effect of the light-emitting chip, but enlarges the package, thereby also increasing the size of the light-emitting unit. For the case of five light-emitting chips, the increase of the width of the heat sink 112 and the increase of the arrangement size can obtain a better heat dissipation effect, for example, when the width of the heat sink 112 is 1.3 mm, the side wall 140 of the package needs to be correspondingly increased to about 10 mm to arrange the five light-emitting chips. In this case, the ratio of the width of one heat sink 112 to the width of the side wall 140 of the package is between 0.1 and 0.15.

As shown in FIG. 33, A represents the distance between the light-emitting points of two adjacent light-emitting chips 113. In some implementations, the ratio of the distance between the light-emitting points of two adjacent light-emitting chips 113 to the width of the side wall 140 of the package ranges from 0.08 to 0.2.

Herein, the distance between the light-emitting points is composed of two parts, one part is the size of the heat sink 112, and the other part is the distance between two heat sinks 112. The width of the heat sink 112 may range from 0.8 mm to 1.3 mm, and the larger the size, the better the heat dissipation. For process and design miniaturization considerations, the distance between two heat sinks 112 may ranges from 0.1 mm to 0.2 mm, and certainly may be larger, but is not conducive to miniaturization.

Based on this, the value of A in FIG. 33 may range from 0.9 mm to 1.5 mm. The ratio of the distance A between the light-emitting points to the width of the side wall 140 of the package may ranges from 0.08 to 0.2. In this range, the arrangement of different numbers of light-emitting chips 113 can be ensured, which is conducive to realization of a miniaturized and integrated laser.

Some embodiments of the reflecting component 150 are described with reference to the accompanying drawings.

As shown in FIG. 35, the laser includes a plurality of reflecting components 150. In some examples, the distance between every two adjacent reflecting components 150 ranges from 0.35 mm to 0.45 mm.

The reflecting component 150 is arranged on the package bottom plate 116, for example, by fixed bonding. The reflecting component 150 may be a reflecting prism or a reflecting mirror. In some embodiments, the plurality of reflecting components 150 are configured corresponding to the plurality of light-emitting chips 113, respectively. When the plurality of light-emitting chips are arranged in the package in a row, the distance between the exit surface of each group of light-emitting chips 113 and the corresponding reflecting component 150 are usually set to be the same, so that positions of reflecting light-emitting points of the plurality of reflecting components 150 have consistency along the arrangement direction of the light-emitting chips, and finally, the light is well emitted to the integrally formed lens assembly 170 correspondingly, specifically emitted to center positions of the plurality of integrally formed collimating lenses correspondingly for emission.

Certainly, in some implementations, the distance between the reflecting component 150 and the exit surface of the corresponding light-emitting chip may be adjusted due to the difference of light-emitting characteristics of the light-emitting chips, so as to improve the position uniformity of the light-emitting points on the reflecting surface.

In some embodiments, one reflecting component 150 may also be configured corresponding to a plurality of light-emitting chips 113. In this case, the reflecting component 150 may be elongated and have at least one reflecting surface.

The reflecting component 150 has a lower surface and a light reflecting surface that reflects light. In addition, the light reflecting surface is inclined relative to the lower surface. That is, the arrangement of the light reflective surface relative to the bottom surface is neither perpendicular nor parallel. A straight line connecting the lower end and the upper end of the light reflecting surface is inclined relative to the lower surface of the reflecting component 150. The angle of the light reflecting surface relative to the lower surface, or the angle of the straight line connecting the lower end and the upper end of the light reflecting surface relative to the lower surface is referred to as the inclination angle of the light reflecting surface.

In the illustrated reflecting component 150, the light reflecting surface is a plane and forms an inclination angle of 45 degrees relative to the lower surface of the reflecting component 150. It should be noted that the light reflecting surface may not be flat, for example, it may be a curved surface. In addition, the inclination angle of the light reflecting surface may not be 45 degrees.

The light reflecting surface of the reflecting component 150 is provided with a film to achieve a light reflecting function. The main material of the reflecting component 150 is, for example, glass such as quartz or BK7 (borosilicate glass), metal such as aluminum, or silicon (Si). The light reflecting film is made of a material having a high light reflectance, for example, metal such as Ag or Al, or is a dielectric multilayer film made of Ta₂O₅/SiO₂, TiO₂/SiO₂, Nb₂O₅/SiO₂, or the like. In addition, in the case where the contour of the reflecting component 150 is formed using a material having a high light reflectance such as metal as the main material, the light reflecting film may be omitted.

A major part of the light emitted by the light-emitting chip 113 strikes to the light reflecting surface of the corresponding reflecting component 150. The light emitted from the light-emitting chip 113 is reflected by the reflecting component 150, so that the length of an optical path of the light incident on the lens can be increased compared to the case where the reflecting component 150 is not interposed. The long optical path can reduce the influence of a mounting deviation between the reflecting component 150 and the light-emitting chip 113. Alternatively, the reflecting component 150 may be omitted, and the exit surface of the light-emitting chip 113 faces the first package 110 above the light-emitting chip.

The light reflecting surface has a reflectance of 90% or more with respect to a peak wavelength of light incident on the light reflecting surface. Alternatively, the reflectance may be 95% or more. Alternatively, the reflectance may be set to 99% or more. The light reflectance is 100% or less or less than 100%.

In some implementations, the distance between the reflecting component 150 and the exit surface of the corresponding light-emitting chip is generally designed to be between 0.2 mm and 0.5 mm, and preferably in the range from 0.35 mm to 0.45 mm. Although not limited in theory, this range is preferred for reflective systems from the standpoint of application and miniaturization.

If the distance between the reflecting component 150 and the exit surface of the corresponding light-emitting chip is excessively small, for example, less than 0.2 mm, the tolerance margin is small, and the process is difficult to implement. If the distance is excessively large, for example, greater than 0.5 mm, since the light beam emitted from the exit surface of the light-emitting chip has a divergence angle, a large light spot is incident on the reflecting surface of the reflecting component, and thus, a certain optical efficiency loss occurs. Therefore, the range from 0.35 mm to 0.45 mm can balance the advantages of the two aspects in terms of the process and efficiency, achieving a miniaturized and high-efficiency system.

Some embodiments of the light-transmitting component 160 are described below with reference to the drawings.

In some optional embodiments, as shown in FIG. 6 or FIG. 35, the laser 10 further includes a light-transmitting component 160, and the light-transmitting component 160 is configured to be soldered to the side wall 140 of the package to form a sealed space. The light-transmitting component 160 may be entirely light-transmissive as a whole, or may be partially light-transmissive in the exit region. For example, a central region may be light-transmissive, while a part region, such as a peripheral region to be soldered to the package, may be provided with a light-blocking film and thus is not light-transmissive.

The light-transmitting component 160 is typically formed using glass as a main material, but the main material is not limited to glass, for example, sapphire may be used as the main material.

The lower surface of the light-transmitting component 160 is bonded to the upper surface 122 of the side wall 140 of the package (upper surface 122 of the package). A metal film is arranged at the bonding region between the light-transmitting component 160 and the side wall 140 of the package, and they are fixed by AuSn soldering. The side wall 140 of the second package 120 is bonded to the light-transmitting component 160 to form a closed space. The closed space is hermetically sealed. By hermetically sealing the second package 120 in this manner, collection of organic substances, or the like, on the light exit surface of the light-emitting chip 113 can be suppressed.

Some embodiments of the lens assembly 170 are described below with reference to the drawings.

The lens assembly 170 typically includes a plurality of integrally formed collimating lens units.

The lens assembly 170 includes an active region and an inactive region.

In some examples, the distance between the light-emitting points of the adjacent light-emitting chips 113, i.e., A as shown in FIG. 33, is 1.25 mm, and correspondingly, the center-to-center distance between two adjacent collimating lens units is 1.25 mm, and the effective aperture of the lens is 3.4 mm, such that the ratio of the center-to-center distance between the lens units to the effective aperture of the lens is 0.37.

In some other embodiments of the present application, the center-to-center distance between two adjacent collimating lens units is 1 mm, the effective aperture of the lens is not changed, and the ratio of the center-to-center distance between the lens units to the effective aperture of the lens is 0.29.

Referring to FIG. 35, the lens assembly 170 is located above an exit path of the light-transmitting component 160. The lens assembly 170 may be integrally formed by collimating lens units 171 having a lens shape and a rectangular base portion 172 supporting the collimating lens unit 171.

The centers of the plurality of collimating lens units 171 correspond to exit points on the reflecting surface of the reflecting component 150, and each collimating lens unit 171 collimates the light beam emitted from the corresponding light-emitting chip 113 and reflected by the reflecting component 150.

The collimating lens unit 171 and the base portion 172 of the lens assembly 170 are both light-transmissive. The lens assembly 170 may be formed of glass such as BK7 and B270.

In some embodiments, the lens assembly 170 may be a cylindrical lens that is only configured to collimate the divergence angle of the laser beam in one direction.

In some embodiments, the lens assembly 170 has an incident surface and an exit surface, and at least one of the incident surface or the exit surface has a lens structure.

The lens assembly 170 has one or more lens surfaces. The one or more lens surfaces are arranged on the upper surface side of the lens assembly 170. It should be noted that the lens surface may also be arranged on the lower surface side of the lens assembly 170.

In some embodiments, the lens assembly 170 may be integrated with the light-transmitting component 160.

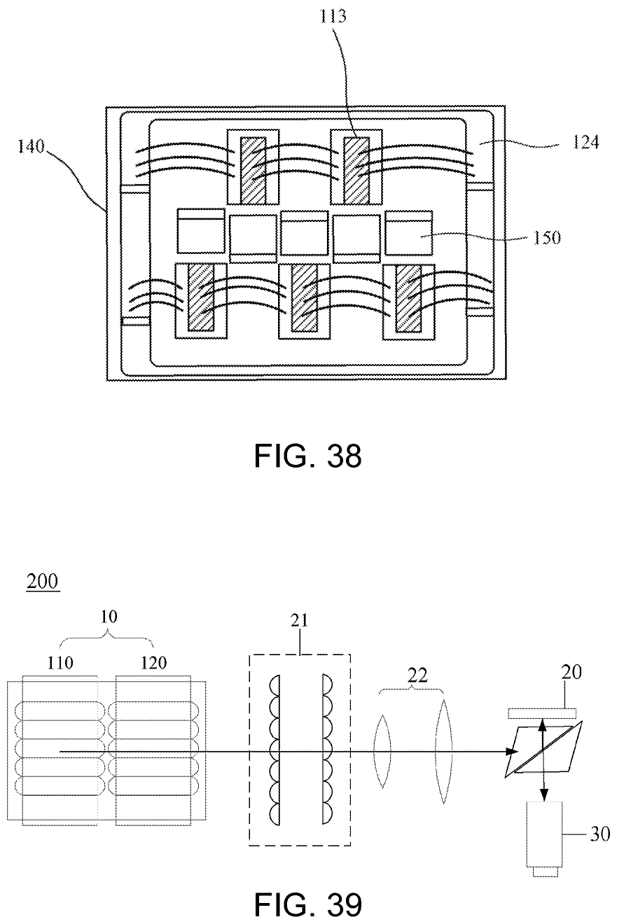

The embodiments of the present application also provide a schematic internal structure diagram of the package. As shown in FIG. 38, a plurality of light-emitting chips 113 are arranged inside the package in two rows, and the numbers of the light-emitting chips in the two rows may be the same or different.

In an example, all the light-emitting chips 113 emit light of one color, such as red laser light. The center wavelengths of the plurality of red light-emitting chips may be set to be different. For example, when the number of the light-emitting chips is five, two light-emitting chips are arranged in the first row, and three light-emitting chips are arranged in the second row. The light-emitting chips in the first are connected in series, the light-emitting chips in the second rows are connected in series, and the serially connected light-emitting chips are connected to the conductive region 124 of the side wall 140 of the package by metal wires. The conductive region 124 includes pairs of connection pads to be connected to the positive electrode and the negative electrode of the light-emitting chip.

In another implementation, the plurality of light-emitting chips 113 include light-emitting chips of different colors, such as a blue light-emitting chip and a green light-emitting chip. Referring again to FIG. 38, in an exemplary implementation, two blue light-emitting chips are arranged in the first row, and all the blue light-emitting chips are connected in series and connected to the conductive region 124 of the side wall 140 of the package via the metal wires respectively. Three green light-emitting chips are arranged in the second row, and all the green light-emitting chips are connected in series and connected to the conductive region 124 of the side wall 140 of the package via the metal wires respectively. At least two groups of connection pads are required to be arranged on the conductive region 124 of the side wall 140 of the package, and are respectively connected to the blue light-emitting chips and the green light-emitting chips.

In some examples, the conductive region 124 of the side wall 140 of the package may include one positive electrode and two negative electrodes, so that the blue light-emitting chips and the green light-emitting chips share the positive electrode. In some other examples, the conductive region 124 of the side wall 140 of the package may include one negative electrode and two positive electrodes, so that the blue light-emitting chips and the green light-emitting chips share the negative electrode.

In the package structure illustrated in FIG. 38, by arranging the light-emitting chips in two rows, the size of the package in the length direction can be reduced.

In addition, it should be noted that the laser 10 according to the embodiments of the present application can be used for a projector, an in-vehicle headlamp, a head-mounted display, an illumination, a display, or the like.

In addition, an embodiment of the present application further provides a laser device, including a laser light source, an optical machine, and a lens, where the laser light source includes the above laser 10.

The optical machine is configured to receive a light beam emitted from the laser 10, the lens is arranged on the optical machine, and the lens project the light beam processed by the optical machine to form an image.

The detailed structure, working principle and function of the laser 10 are described in detail in the previous embodiments, and are not repeated herein.

It should be noted that the laser device 200 includes the laser 10, a light valve component 20, and the lens 30. The light valve component is, for example, a Digital Micromirror Device (DMD) chip. The laser device 200 further includes a main control circuit board, an audio processing system, a sound system, and a heat dissipating member.

The laser 10 is configured to emit a laser beam to the light valve component 20. Typically, the three-color laser beam emitted by the laser 10 is shaped before reaching the light valve component 20, for example, by passing through a homogenizing component 21 and a lens group 22, so as to be shaped to conform to the incident size and angle of the light valve component 20.

In the laser device 200, the light valve component is connected to a display control chip in a main control circuit, and the main control circuit is further configured to drive the laser 10 to emit light.

In this example, the laser 10 is driven to sequentially emit three-color laser beams which form an illumination beam through shaping by system optical components, and then, the illumination beam is modulated by the light valve component 20. The light valve component 20 receives the three-primary-color illumination beam under driving of a display control chip, and the image beam carrying an image signal is projected to the lens through reflection of thousands of small mirrors on the surface of the light valve component, and the lens magnifies the image beam by the lens group to form an image.

In the laser device 200 in the present example, the laser 10 emits the three-color laser beams, so that a projected image has higher brightness and better color gamut.

Furthermore, as shown in FIG. 39, since three-color laser light-emitting chips with different high light-emitting powers are encapsulated in only two packages in the laser 10, the space occupied during assembly of the optical path system is small, a corresponding heat dissipating assembly and a driving control assembly may also be miniaturized correspondingly, and after the light beam is emitted from the light source, the downstream optical path system also has miniaturization providing conditions, thereby facilitating the miniaturization of the whole laser device.

It can be seen that the laser device includes any one of the above lasers, and has corresponding beneficial effects, which are not repeated herein to avoid repeated descriptions.

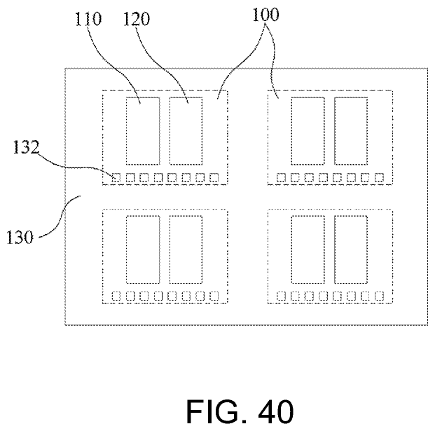

FIG. 40 is a schematic structural diagram of the laser according to the embodiment of the present application. Referring to FIG. 40, the mounting substrate 130 of the laser is provided with a plurality of light-emitting units 100. The internal structure of each light-emitting unit 100 may be implemented with reference to the internal structure of any one of the light-emitting units described above. In an example, the plurality of light-emitting units 100 on the mounting substrate 130 are arranged in an array (for example, two rows and two columns are taken as an example in FIG. 40), the internal structures of the light-emitting units 100 are identical, and the mounting substrate 130 has an identical internal structure in the region corresponding to each light-emitting unit 100. For example, each of the light-emitting units 100 may have the light-emitting unit structure including the first package 110 and the second package 120 as shown in FIG. 5, FIG. 6 or FIG. 11, and the mounting substrate 130 is provided with a row of connection pads 132 at a position corresponding to each of the light-emitting units 100. Further, the following content is not shown in FIG. 40: the connection pattern of the mounting substrate 130 may include conductive patterns respectively corresponding to the light-emitting units 100, and each of the light-emitting units 100 is fixed on and electrically connected to the corresponding conductive pattern. In other examples, different light-emitting units 100 on the same mounting substrate 130 may have different internal structures.

In descriptions of the present application, it should be understood that, directions or positional relationships indicated by terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “anticlockwise”, “axial”, “radial”, “circumferential” etc. are based on orientations or positional relationships shown in the accompanying drawings, and they are used only for describing the present application and for description simplicity, but do not indicate or imply that an indicated device or element must have a specific orientation or be constructed and operated in a specific orientation. Therefore, it cannot be understood as a limitation on the present application.

In addition, the terms such as “first” and “second” are used herein for purposes of description and are not intended to indicate or imply relative importance or significance or to imply the number of indicated technical features. Thus, the feature defined with “first” and “second” may include at least one of this feature explicitly or implicitly. In the description of the present application, “a plurality of” means at least two, such as two, three, or the like, unless otherwise specified.

It will be understood by those skilled in the art that all or part of the steps for implementing the above embodiments may be implemented by hardware, or may be implemented by a program instructing relevant hardware, the program may be stored in a computer-readable storage medium, and the storage medium may be a read-only memory, a magnetic disk or an optical disk.

The above description is only a preferred embodiment of this application and is not intended to limit this application, and any modifications, equivalents and improvements made within the spirit and principle of the present application should be included in the protection scope of the present application.

What is claimed is:

1. A laser, comprising:
a mounting substrate comprising a connection pattern, a plurality of connection pads, and a plurality of in-substrate connection wires, at least four of the connection pads being electrically connected to the connection pattern via the plurality of in-substrate connection wires; and
a light-emitting unit, the light-emitting unit comprising at least one package and a plurality of light-emitting chips arranged in the at least one package, a side of the at least one package facing the mounting substrate comprising a conductive structure, the connection pattern comprising a conductive pattern, the light-emitting unit being fixed on the conductive pattern and electrically connected to the conductive pattern, a side wall of the at least one package being provided with at least one side wall connection wire, the at least one light-emitting chip being electrically connected to one side wall connection wire in the side wall of the package where the light-emitting chip is located,
wherein the light-emitting chips in the light-emitting unit comprise at least two types of light-emitting chips that emit light of different colors, the plurality of connection pads comprise at least two groups of connection pads, each group of connection pads corresponding to one type of the light-emitting chips in the light-emitting unit, each group of connection pads comprises two connection pads, and each group of connection pads is electrically connected to the light-emitting chips of the corresponding type.

2. The laser according to claim 1, wherein the light-emitting unit further comprises a plurality of heat sinks corresponding to the plurality of light-emitting chips, and each of the light-emitting chips is mounted onto a package bottom plate of the package via the corresponding heat sink.

3. The laser according to claim 2, wherein the conductive pattern comprises at least one conductive base in one-to-one correspondence with the at least one package, and each of the light-emitting chips is electrically connected to the conductive base corresponding to the package where the light-emitting chip is located via the corresponding heat sink.

4. The laser according to claim 2, wherein the plurality of light-emitting chips in each package are arranged in at least one row, and for each heat sink, a ratio of a length of the heat sink to a width of the heat sink ranges from 1 to 3.5.

5. The laser according to claim 4, wherein the ratio of the length of the heat sink to the width of the heat sink ranges from 1.5 to 3.5; or, the ratio of the length of the heat sink to the width of each heat sink ranges from 1 to 1.7.

6. The laser according to claim 5, wherein the length of the heat sink is H, and H=Ho×K1+K2, wherein Ho is a length of the light-emitting chip, K1 is an accommodation coefficient, and K2 is a constant;
and/or,
the width of the heat sink is L, and L≥(L0+2 tan θ×D), wherein L0 is a width of the light-emitting chip, D is a thickness of the heat sink, and θ is an angle of heat conduction from the light-emitting chip to the heat sink.

7. The laser according to claim 2, wherein the laser satisfies one of the following conditions (1) and (2):
(1) a ratio of a width of each heat sink to a width of the package where the heat sink is located ranges from 0.05 to 0.2; and/or a ratio of a sum of the widths of the heat sinks in each package to the width of the package ranges from 0.4 to 0.8;
(2) the ratio of the width of each heat sink to the width of the package where the heat sink is located ranges from 0.07 to 0.12; and/or the ratio of the sum of the widths of the heat sinks in each package to the width of the package ranges from 0.1 to 0.15.

8. The laser according to claim 2, wherein each of the light-emitting chips is mounted on a region of the corresponding heat sink close to the connection pads.

9. The laser according to claim 1, wherein more than one light-emitting chip that emits light of the same color within the light-emitting unit has at least two different center wavelengths.

10. The laser according to claim 9, wherein a difference between any two of the at least two different center wavelengths is greater than or equal to 3 nm.

11. The laser according to claim 1, wherein more than three light-emitting chips that emit light of the same color within the light-emitting unit have at least three different center wavelengths.

12. The laser according to claim 9, wherein every two light-emitting chips with different center wavelengths are arranged adjacent to each other, and every two light-emitting chips with the same center wavelength are spaced apart from each other.

13. The laser according to claim 1, wherein each of the light-emitting chips has a plurality of light-emitting points, and a ratio of a distance between the light-emitting points of two adjacent light-emitting chips in the same package to a width of the package ranges from 0.08 to 0.2; and/or
the light-emitting unit further comprises a plurality of reflecting components arranged in the at least one package, and a distance between every two adjacent reflecting components in the same package ranges from 0.35 mm to 0.45 mm.

14. The laser according to claim 1, wherein orthographic projections of the plurality of connection pads in a plane of the mounting substrate are at least partially overlapped with orthographic projection of the plurality of in-substrate connection wires in the plane of the mounting substrate, an orthographic projection of the connection pattern in the plane of the mounting substrate is at least partially overlapped with the orthographic projections of the plurality of in-substrate connection wires in the plane of the mounting substrate, and an orthographic projection of the conductive structure in the plane of the mounting substrate is at least partially overlapped with the orthographic projection of the connection pattern in the plane of the mounting substrate; and
in the plane of the mounting substrate, the plurality of connection pads are located on the same side edge of the mounting substrate.

15. The laser according to claim 14, wherein each of the connection pads has a length of 1.3 mm to 1.7 mm in an arrangement direction of the plurality of connection pads; and along the arrangement direction of the plurality of connection pads, a distance between every two adjacent connection pads is 0.8 mm to 1.2 mm.

16. The laser according to claim 1, wherein each of the light-emitting chips is one of first-type light-emitting chips, second-type light-emitting chips, and third-type light-emitting chips with different light-emitting colors;
the light-emitting chips that emitting light of the same color in the same package are connected in series and are respectively connected to the two connection pads in the corresponding group of connection pads;
wherein a number of the connection pads corresponding to each package is two times a number of colors of light emitted by the light-emitting chips in the package, the two connection pads in each group of connection pads are respectively a positive polarity pad and a negative polarity pad, and the two connection pads in one group of connection pads connected to the light-emitting chips that emit light of the same color are adjacent to each other.

17. The laser according to claim 16, wherein the conductive structure comprises a plurality of bottom pads, the conductive pattern comprises a plurality of transition pads, the plural transition pads are electrically connected to the plurality of bottom pads of the conductive structure in a one-to-one correspondence manner, and at least one of the plurality of bottom pads is electrically connected to one of the side wall connection wires in the side wall of the package where the bottom pads are located.

18. The laser according to claim 16, wherein a wavelength of light emitted by the third-type light-emitting chip is greater than wavelengths of light emitted by the first-type light-emitting chip and the second-type light-emitting chip; and
at least one light-emitting unit comprises a first package and a second package which are arranged side by side, each light-emitting chip in the first package is the third-type light-emitting chip, and each light-emitting chip in the second package is one of the first-type light-emitting chip and the second-type light-emitting chip.

19. The laser according to claim 18, wherein the light-emitting unit further comprises a plurality of heat sinks in one-to-one correspondence with the plurality of light-emitting chips, each of the light-emitting chips is mounted onto a package bottom plate of the package via the corresponding heat sink, and each third-type light-emitting chip is mounted to a region of the corresponding heat sink close to the group of connection pads corresponding to the third-type light-emitting chip; and/or
Zener diodes are arranged on the heat sink corresponding to the first-type light-emitting chip and the heat sink corresponding to the second-type light-emitting chip.

20. A laser device comprising the laser according to claim 1, a light valve assembly, and a lens.
